(19) United States
(12) Patent Application Publication
(10) Pub. No.: US 2025/0006535 A1
(43) Pub. Date: Jan. 2, 2025

(54) SUBSTRATE PROCESSING SYSTEM

(71) Applicant: SCREEN Holdings Co., Ltd., Kyoto (JP)

(72) Inventors: Akihiro IWASAKI, Kyoto (JP); Shinichi TANIGUCHI, Kyoto (JP)

(21) Appl. No.: 18/755,637

(22) Filed: Jun. 26, 2024

(30) Foreign Application Priority Data
Jun. 27, 2023 (JP) 2023-105021

(51) Int. Cl. H01L 21/677; C23F 1/08; H01L 21/67

(52) U.S. Cl. CPC H01L 21/67781; H01L 21/67086; C23F 1/08

(57) ABSTRACT

A substrate processing system that continuously performs a batch process to collectively perform a plurality of substrates, and a single-wafer process to process substrates one by one, the substrate processing system including: a batch processing apparatus that performs the batch process; at least one single-wafer processing apparatus that performs the single-wafer process on a batch-processed substrate; a relay transport mechanism provided between a loading position and an unloading position, and capable of transporting substrates in a horizontal orientation one by one to the unloading position along a substrate transport path; and a rotation adjustment mechanism including a turntable capable of adjusting the position of a notch on each of the substrates in the horizontal orientation by rotating the substrates one by one on the loading position side or at the unloading position.

This application claims priority to Japanese Patent Application No. 2023-105021 filed Jun. 27, 2023, the subject matter of which is incorporated herein by reference in entirety.

### BACKGROUND OF THE INVENTION

### Field of the Invention

The present invention relates to a substrate processing system that performs a predetermined process on various substrates, including semiconductor substrates, substrates for flat panel displays (FPD) such as liquid crystal displays and organic electroluminescence (EL) displays, glass substrates for photomasks, and optical disk substrates.

### Description of the Related Art

Examples of conventional apparatuses of this type include batch-type modules and single-wafer-type modules (e.g., see JP 2021-64654 A). The batch-type module collectively performs a predetermined process on a plurality of substrates. The single-wafer-type module performs a predetermined process on each substrate. Each of the batch-type module and the single-wafer-type module has unique advantages. The substrate processing apparatus including both the batch-type module and the single-wafer-type module has the advantages of both, thereby realizing a configuration with advantages over a batch-type substrate processing apparatus or a single-wafer-type substrate processing apparatus.

According to the configuration of Japanese Patent Application Laid-Open No. 2021-64654, a plurality of substrates are collectively immersed in a batch processing tank. The substrates that have completed the batch process are transported to a single-wafer processing part one by one. As described above, according to the conventional configuration, a plurality of substrates stored in a carrier are transported in the same transport mode and returned to the carrier. The orientations of the plurality of substrates stored in the carrier are aligned such that the array of devices formed on the substrates face a common direction. In a conventional substrate processing apparatus, when a substrate process is performed on a plurality of substrates with a uniform orientation in a carrier, the substrate process is executed while their orientation uniformity is maintained, and the plurality of substrates are returned with their orientations aligned.

### LIST OF DOCUMENTS

JP 2021-64654

However, the above configuration cannot realize all the requirements for the substrate processing apparatus. Indeed, in the conventional configuration, all substrates are transported in the same transport mode in the course of the substrate process, so that the substrates that have been dispensed from the carrier with a unified orientation, subjected to the substrate process, and then housed again are uniformly oriented. However, when a different transport mode is adopted depending on the substrates in the substrate processing apparatus, the orientations of the substrates that have been subjected to the substrate process and housed in the carrier may not coincide. Such misalignment of the orientations of the substrates that have been subjected to the substrate process and housed in the carrier may cause inconvenience in subsequent processes.

### SUMMARY OF THE INVENTION

The present invention has been made in view of such circumstances, and an object of the present invention is to provide a substrate processing system that includes a batch-type module and a single-wafer-type module and can respond to various requirements for substrate orientation.

To solve the above problems, the present invention has the following configurations.

That is, the present invention is a substrate processing system that continuously performs a batch process to collectively perform a plurality of substrates, and a single-wafer process to process substrates one by one, the substrate processing system including: a batch processing apparatus that performs the batch process; at least one single-wafer processing apparatus that performs the single-wafer process on a substrate subjected to the batch process; at least one relay apparatus with two positions defined, the two positions being a loading position to receive a substrate subjected to the batch process from the batch processing apparatus and an unloading position to pass the substrate received at the loading position to the single-wafer processing apparatus. The batch processing apparatus includes at least one batch processing tank capable of collectively performing an immersion process on a plurality of substrates in a vertical orientation, the single-wafer processing apparatus includes a plurality of single-wafer processing chambers capable of performing a drying process on substrates in a horizontal orientation one by one, and the relay apparatus includes an orientation conversion mechanism capable of converting a plurality of substrates from the vertical orientation to the horizontal orientation on a side of the loading position, a relay transport mechanism provided between the loading position and the unloading position, and capable of transporting the substrates in the horizontal orientation one by one to the unloading position along a substrate transport path, and a rotation adjustment mechanism including a turntable capable of adjusting a position of a notch on each of the substrates in the horizontal orientation by rotating the substrates one by one on the side of the loading position or at the unloading position.

[Action and Effects] According to the above invention, in the substrate processing system configured by coupling the batch processing apparatus and the single-wafer processing apparatus through the relay apparatus, it is possible to realize the requirements for the substrate processing system. The relay apparatus of the present invention includes the rotation adjustment mechanism including the turntable capable of adjusting the position of a notch on each of substrates on the loading position side where the relay apparatus acquires the substrate or at the unloading position where the relay apparatus dispenses the substrate. The orientation of the substrate to be dispensed from the relay apparatus to the single-wafer processing apparatus can be changed as desired by the rotation adjustment mechanism. Changing the operation of the rotation adjustment mechanism enables the orientation of the batch-processed substrate passed to the single-wafer processing apparatus to be aligned in a predetermined direction.

Further, in the substrate processing system described above, preferably, the batch processing apparatus includes a substrate holding mechanism that supports a first substrate group in the vertical orientation and a second substrate group in the vertical orientation, the substrate holding mechanism supporting a lot formed by combining a first substrate constituting the first substrate group and a second substrate constituting the second substrate group to cause a device surface of the first substrate and a device surface of the second substrate to face each other, the relay apparatus includes a substrate group sorting mechanism capable of sorting a lot into the first substrate and the second substrate, the orientation conversion mechanism collectively converts the first substrate sorted and the second substrate sorted from the vertical orientation to the horizontal orientation, and when an orientation of a notch on the first substrate and an orientation of a notch on the second substrate are different, the first substrate and the second substrate having been converted into the horizontal orientation by the orientation conversion mechanism, the rotation adjustment mechanism rotates the second substrate at an angle different from a rotation angle of the first substrate to cause the orientation of the notch on the first substrate and the orientation of the notch on the second substrate to coincide.

[Action and Effects] According to such a configuration, it is possible to provide a substrate processing system capable of aligning the orientations of the substrates in a predetermined direction even if the substrates are arrayed in a face-to-face manner to form a lot. When two substrate groups are combined and arrayed such that the device surface of the first substrate and the device surface of the second substrate face each other, a lot in which the first substrates and the second substrates are alternately arrayed is formed. When the lot is then sorted into the first substrate and the second substrate, a situation arises where the orientation of the notch on the first substrate and the orientation of the notch on the second substrate are different from each other. According to the above configuration, the rotation adjustment mechanism rotates the substrates so that the rotation angle of the first substrate and the rotation angle of the second substrate are different from each other, whereby the orientation of the notch on the first substrate and the orientation of the notch on the second substrate can be caused to coincide.

Further, in the substrate processing system described above, preferably, the rotation adjustment mechanism includes a substrate lifting mechanism capable of lifting a substrate between a first position on an upper side and a second position on a lower side, and the substrate lifting mechanism lifts a substrate, held by the relay transport mechanism at an intermediate position between the first position and the second position, to the first position to receive the substrate from the relay transport mechanism, and lowers the substrate received to the second position to place the substrate on the turntable.

[Action and Effects] According to such a configuration, the substrate is moved up and down between the first position on the upper side, the intermediate position, and the second position on the lower side, and can receive the substrate, rotate the substrate, and dispense the substrate. According to such a configuration, the configuration of the rotation adjustment mechanism can be made simpler.

Further, in the substrate processing system described above, the rotation adjustment mechanism preferably includes a substrate shift mechanism that shifts the substrate at the first position to cause a center of the substrate to coincide with a rotation center of the turntable.

[Action and Effects] According to such a configuration, the substrate at the first position is shifted such that its center coincides with the center position of the turntable. With this configuration, the orientation of the substrate can be reliably set to a predetermined orientation, and by placing the substrate at an ideal position, the substrate can be reliably transported by the sheet transport mechanism.

Further, in the substrate processing system described above, the substrate lifting mechanism preferably includes a plurality of support pins that protrude and retract synchronously, and is provided at a position avoiding a plurality of extensions extending from a rotation center of the turntable located at an initial position.

[Action and Effects] According to such a configuration, the substrate lifting mechanism includes the plurality of support pins that protrude and retract synchronously, and is provided at a position avoiding the plurality of extensions extending from the rotation center of the turntable located at the initial position. With such a configuration, it is possible to reliably configure the rotation adjustment mechanism including both the substrate lifting mechanism and the mechanism for rotating the substrate.

Further, in the substrate processing system described above, the rotation adjustment mechanism preferably includes a pure water replenishing mechanism that replenishes pure water to a substrate received.

[Action and Effects] According to such a configuration, since the rotation adjustment mechanism includes the pure water replenishing mechanism that replenishes pure water to the received substrate, the substrate is not dried during the operation in the rotation adjustment mechanism.

Further, in the substrate processing system described above, the rotation adjustment mechanism preferably includes a sensor that detects a position of a notch on a substrate on the turntable.

[Action and Effects] According to such a configuration, since the rotation adjustment mechanism includes the sensor that detects the position of the notch on the substrate on the turntable, it is possible to actually measure and correct a slight deviation in direction seen between the substrates.

According to the present invention, it is possible to provide a substrate processing system that includes a batch-type module and a single-wafer-type module and can respond to various requirements for substrate orientation.

### BRIEF DESCRIPTION OF THE DRAWINGS

FIG. 1 is a plan view for explaining an overall configuration of a substrate processing system according to an embodiment;

FIG. 2 is a plan view for explaining an overall configuration of a batch processing apparatus in the embodiment;

FIG. 3 is a schematic diagram illustrating a configuration of an HVC orientation converter in the embodiment;

FIGS. 4A to 4F are schematic diagrams illustrating a configuration of a first orientation conversion mechanism in the embodiment;

FIG. 5A is a schematic diagram illustrating an operation of a relay apparatus in the embodiment;

FIG. 5B is a schematic diagram for explaining the operation of the relay apparatus in the embodiment;

FIG. 6A is a schematic diagram for explaining the operation of the relay apparatus in the embodiment;

FIG. 6B is a schematic diagram for explaining the operation of the relay apparatus in the embodiment;

FIG. 6C is a schematic diagram for explaining the operation of the relay apparatus in the embodiment;

FIG. 7A is a schematic diagram for explaining the operation of the relay apparatus in the embodiment;

FIG. 7B is a schematic diagram for explaining the operation of the relay apparatus in the embodiment;

FIG. 7C is a schematic diagram for explaining the operation of the relay apparatus in the embodiment;

FIG. 8A is a schematic diagram for explaining the operation of the relay apparatus in the embodiment;

FIG. 8B is a schematic diagram for explaining the operation of the relay apparatus in the embodiment;

FIG. 9A is a schematic diagram for explaining the operation of the relay apparatus in the embodiment;

FIG. 9B is a schematic diagram for explaining the operation of the relay apparatus in the embodiment;

FIG. 9C is a schematic diagram for explaining the operation of the relay apparatus in the embodiment;

FIG. 10A is a schematic diagram for explaining the operation of the relay apparatus in the embodiment;

FIG. 10B is a schematic diagram for explaining the operation of the relay apparatus in the embodiment;

FIG. 10C is a schematic diagram for explaining the operation of the relay apparatus in the embodiment;

FIG. 11A is a schematic diagram for explaining the operation of the relay apparatus in the embodiment;

FIG. 11B is a schematic diagram for explaining the operation of the relay apparatus in the embodiment;

FIG. 11C is a schematic diagram for explaining the operation of the relay apparatus in the embodiment;

FIG. 11D is a schematic diagram for explaining the operation of the relay apparatus in the embodiment;

FIG. 12A is a schematic diagram for explaining the operation of the relay apparatus in the embodiment;

FIG. 12B is a schematic diagram for explaining the operation of the relay apparatus in the embodiment;

FIG. 12C is a schematic diagram for explaining the operation of the relay apparatus in the embodiment;

FIG. 12D is a schematic diagram for explaining the operation of the relay apparatus in the embodiment;

FIG. 13A is a schematic diagram for explaining the operation of the relay apparatus in the embodiment;

FIG. 13B is a schematic diagram for explaining the operation of the relay apparatus in the embodiment;

FIG. 13C is a schematic diagram for explaining the operation of the relay apparatus in the embodiment;

FIG. 14A is a schematic diagram for explaining the operation of the relay apparatus in the embodiment;

FIG. 14B is a schematic diagram for explaining the operation of the relay apparatus in the embodiment;

FIG. 14C is a schematic diagram for explaining the operation of the relay apparatus in the embodiment;

FIG. 15 is a schematic diagram illustrating a transition of a notch position on a substrate in the embodiment;

FIG. 16 is a schematic diagram illustrating a transition of a notch position on a substrate in the embodiment;

FIG. 17 is a schematic diagram illustrating a configuration of a rotation adjustment mechanism in the embodiment;

FIG. 18A is a schematic diagram illustrating the configuration of the rotation adjustment mechanism in the embodiment;

FIG. 18B is a schematic diagram illustrating the configuration of the rotation adjustment mechanism in the embodiment;

FIG. 19 is a flowchart for explaining the operation of the rotation adjustment mechanism in the embodiment;

FIG. 20A is a schematic view for explaining the operation of the rotation adjustment mechanism in the embodiment;

FIG. 20B is a schematic view for explaining the operation of the rotation adjustment mechanism in the embodiment;

FIG. 21A is a schematic view for explaining the operation of the rotation adjustment mechanism in the embodiment;

FIG. 21B is a schematic view for explaining the operation of the rotation adjustment mechanism in the embodiment;

FIG. 22A is a schematic view for explaining the operation of the rotation adjustment mechanism in the embodiment;

FIG. 22B is a schematic view for explaining the operation of the rotation adjustment mechanism in the embodiment;

FIG. 23A is a schematic view for explaining the operation of the rotation adjustment mechanism in the embodiment;

FIG. 23B is a schematic view for explaining the operation of the rotation adjustment mechanism in the embodiment;

FIG. 24A is a schematic view for explaining the operation of the rotation adjustment mechanism in the embodiment;

FIG. 24B is a schematic view for explaining the operation of the rotation adjustment mechanism in the embodiment;

FIG. 25A is a schematic view for explaining the operation of the rotation adjustment mechanism in the embodiment;

FIG. 25B is a schematic view for explaining the operation of the rotation adjustment mechanism in the embodiment;

FIG. 26A is a schematic view for explaining the operation of the rotation adjustment mechanism in the embodiment;

FIG. 26B is a schematic view for explaining the operation of the rotation adjustment mechanism in the embodiment;

FIG. 27A is a schematic view for explaining the operation of the rotation adjustment mechanism in the embodiment;

FIG. 27B is a schematic view for explaining the operation of the rotation adjustment mechanism in the embodiment;

FIG. 28 is a schematic view for explaining the operation of the rotation adjustment mechanism in the embodiment;

FIG. 29 is a plan view for explaining a configuration of a single-wafer processing apparatus according to the embodiment;

FIG. 30 is a flowchart for explaining substrate transport in the embodiment;

FIG. 31 is a schematic diagram illustrating the substrate transport in the embodiment;

FIG. 32 is a schematic diagram illustrating the substrate transport in the embodiment; and

FIG. 33 is a schematic diagram illustrating a modification of the present invention.

### DESCRIPTION OF THE PREFERRED EMBODIMENTS

Hereinafter, an embodiment of the present invention will be described with reference to the drawings. The substrate processing system of the present invention continuously performs a batch process to collectively process a plurality of substrates W, and a single-wafer process to process substrates W one by one, and has a configuration in which a batch processing apparatus related to the batch process and a single-wafer processing apparatus related to the single-wafer process are coupled through a relay apparatus.

The substrate processing system according to the present invention performs, for example, processes such as chemical treatment, a cleaning process, and a drying process on the substrate W. The substrate processing system adopts a processing method (so-called hybrid method) that uses both a batch-type processing method, in which a plurality of substrates W are collectively processed, and a single-wafer-type processing method, in which substrates W are processed one by one, in combination. The batch-type processing method is a processing method in which a plurality of substrates W arrayed in the vertical orientation are collectively processed. The single-wafer processing method is a processing method to process the substrates W in a horizontal orientation one by one. The substrate processing system of the present invention continuously performs a batch process to collectively perform a plurality of substrates, and a single-wafer process to process substrates one by one.

### 1. Overall Configuration

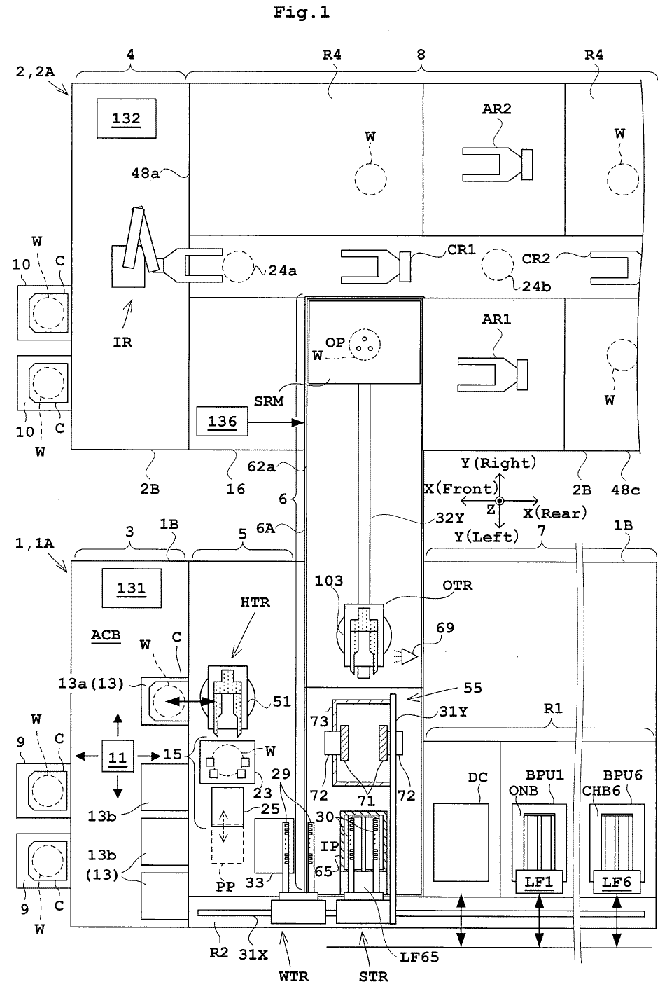

As illustrated in FIG. 1, the substrate processing system includes a batch processing apparatus 1 and a single-wafer processing apparatus 2 that are individually configured, and a relay apparatus 6 that connects the apparatuses 1, 2. The batch processing apparatus 1 relates to a batch process to collectively perform a plurality of substrates, and the single-wafer processing apparatus 2 relates to a single-wafer process to process substrates one by one. The relay apparatus 6 is configured to transport the batch-processed substrate from the batch processing apparatus 1 to the single-wafer processing apparatus 2, and has a crosslinked structure provided at a position interposed between the batch processing apparatus 1 and the single-wafer processing apparatus 2.

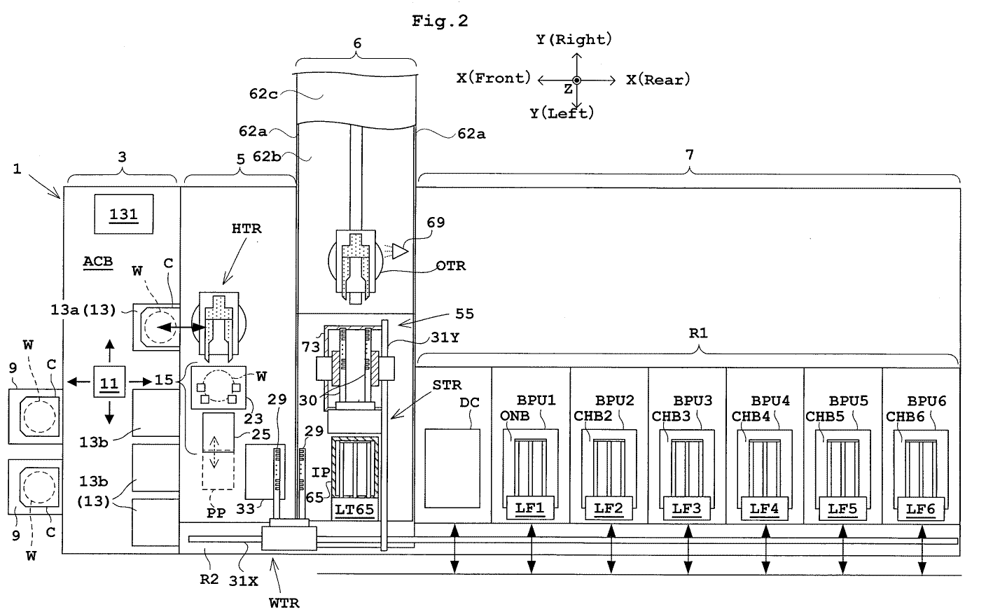

As illustrated in FIG. 1, each of the batch processing apparatus 1 and the single-wafer processing apparatus 2 has blocks partitioned by partition walls. That is, the batch processing apparatus 1 has a stocker block 3, a transfer block 5 adjacent to the stocker block 3, and a batch processing block 7 adjacent to the transfer block 5. FIG. 2 illustrates a specific configuration of the batch processing block 7 in the batch processing apparatus 1. Meanwhile, the single-wafer processing apparatus 2 has an indexer block 4 and a single-wafer processing block 8 adjacent to the indexer block 4.

The batch processing apparatus 1 is configured to perform the batch process, and includes a first casing 1A that houses each block constituting the batch processing apparatus 1. The single-wafer processing apparatus 2 is configured to perform the single-wafer process on the batch-processed substrate W, and includes a second casing 2A that houses each block constituting the single-wafer processing apparatus 2. The first casing 1A includes a first load port 9 protruding from a first wall surface orthogonal to the Y direction from the batch processing block 7 toward the transfer block 5 among wall surfaces constituting the first casing. The second casing 2A includes a second load port 10 protruding from a second wall surface orthogonal to the Y direction among wall surfaces constituting the second casing 2A, and the second load port 10 is at the same position as the first load port 9 in the Y direction. The carrier C can be placed on the second load port 10.

In the present specification, for convenience, a direction in which the stocker block 3, the transfer block 5, and the batch processing block 7 in the batch processing apparatus 1 are arrayed is referred to as a “front-rear direction X”. The front-rear direction X is also a direction in which the indexer blocks 4 and the single-wafer processing blocks 8 in the single-wafer processing apparatus 2 are arrayed. The front-rear direction X extends horizontally. Of the front-rear direction X, the direction from the transfer block 5 toward the stocker block 3 in the batch processing apparatus 1 is referred to as “front”. The front is also a direction from the single-wafer processing block 8 to the indexer block 4 in the single-wafer processing apparatus 2. A direction opposite to the front is referred to as “rear”. A direction extending horizontally orthogonal to the front-rear direction X is referred to as a “width direction Y”. One direction of the “width direction Y” is referred to as a “right side” for convenience, and the other direction is referred to as a “left side” for convenience. A direction (height direction) orthogonal to the front-rear direction X and the width direction Y is referred to as a “vertical direction Z” for convenience. In each figure, front, back, right, left, top, and bottom are appropriately shown for reference.

In the substrate processing system of the present invention, first, the substrates W are subjected to the batch process by the batch processing apparatus 1, and the batch-processed substrates W are transported to the single-wafer processing apparatus 2 by the relay apparatus 6. Then, the single-wafer processing apparatus 2 performs the single-wafer process on the substrate W to complete all the steps of the substrate process. Hereinafter, the specific configurations of the batch processing apparatus 1, the relay apparatus 6, and the single-wafer processing apparatus 2 will be described in this order along the flow of the substrates W in the substrate processing system of the present invention.

### 2. Batch Processing Apparatus: Stoker Block

The stocker block 3 includes a first load port 9 that serves as an entrance when a carrier C, which houses a plurality of substrates W in the horizontal orientation at predetermined vertical intervals, is fed into the block. The first load port 9 protrudes from the outer wall of the stocker block 3 extending in the width direction (Y direction).

A plurality of (e.g., 25) substrates W are laminated and housed in the horizontal orientation at regular intervals in one carrier C. The carrier C, which houses the unprocessed substrates W loaded into the batch processing apparatus 1, is first placed on the first load port 9. The carrier C is formed with a plurality of grooves (not illustrated) extending in the horizontal direction to store the substrates W with their surfaces separated from each other. One substrate W is inserted into each of the grooves. An example of the carrier C is a sealed front opening unified pod (FOUP). In the present invention, an open container may be adopted as the carrier C. The internal structure of the stocker block 3 will be described. The stocker block 3 includes a transport housing ACB that stocks and manages the carrier C. The transport housing ACB includes a carrier transport mechanism 11 that transports the carrier C and a shelf 13 on which the carrier C is placed. The number of carriers C that can be stocked by the stocker block 3 is one or more.

The stocker block 3 includes a plurality of shelves 13 on which the carrier Cis placed. The shelf 13 is provided on a partition wall separating the stocker block 3 and the transfer block 5. The shelf 13 includes a shelf 13b for stocking where the carrier C is simply temporarily placed, and a carrier placement shelf 13a for substrate extraction that is accessed by a first substrate transport mechanism HTR included in the transfer block 5.

The carrier placement shelf 13a is configured for placing a carrier that houses a plurality of substrates in the horizontal orientation at predetermined vertical intervals. The carrier placement shelf 13a is configured for placing the carrier C from which the substrate W is extracted. In the present embodiment, one carrier placement shelf 13a is provided, but a plurality of carrier placement shelves 13a may be provided. The carrier transport mechanism 11 takes in the carrier C, which houses the unprocessed substrate W, from the first load port 9 and places the carrier C on the carrier placement shelf 13a for substrate extraction. At this time, the carrier transport mechanism 11 can also temporarily place the carrier C on the stock shelf 13b before placing the carrier C on the carrier placement shelf 13a. The number of carrier placement shelves 13a included in the stocker block 3 is one or more.

### 3. Batch Processing Apparatus: Transfer Block

The transfer block 5 is adjacent to the carrier placement shelf 13a. The transfer block 5 is disposed adjacent to the rear of the stocker block 3. The transfer block 5 includes a first substrate transport mechanism HTR that can access the carrier C placed on the carrier placement shelf 13a for substrate extraction, an HVC orientation converter 23 that collectively converts the orientations of the plurality of substrates W from the horizontal orientation to the vertical orientation, and a pusher mechanism 25. The HVC orientation converter 23 constitutes a first orientation conversion mechanism 15. The first orientation conversion mechanism 15 collectively converts the plurality of substrates W, extracted from the carrier C, from the horizontal to vertical orientation. Further, in the transfer block 5, a substrate delivery position PP for delivery of the plurality of substrates W to a second substrate transport mechanism WTR provided in the collective transport region R2 is set. The first substrate transport mechanism HTR, the HVC orientation converter 23, and the pusher mechanism 25 are arrayed in this order in the Y direction.

The first substrate transport mechanism HTR is configured to collectively extract a plurality of substrates W from the carrier C placed on the carrier placement shelf 13a. The first substrate transport mechanism HTR is provided on the right of the rear of the transport housing ACB included in the stocker block 3. The first substrate transport mechanism HTR is a mechanism for collectively extracting a plurality of substrates W from the carrier C placed on the carrier placement shelf 13a for substrate extraction and housing. The first substrate transport mechanism HTR includes a plurality of (e.g., 25) hands 51 that collectively transport a plurality of substrates W. One hand 51 supports one substrate W. The first substrate transport mechanism HTR collectively extracts a plurality of (e.g., 25) substrates W from the carrier C placed on the carrier placement shelf 13a of the stocker block 3. Then, the first substrate transport mechanism HTR can transport the plurality of gripped substrates W to a support table 23A of the HVC orientation converter 23. The HVC orientation converter 23 converts the plurality of received substrates W in the horizontal orientation into the vertical orientation. The pusher mechanism 25 is configured to hold the plurality of substrates W in the vertical orientation and move the substrates W up, down, left, and right.

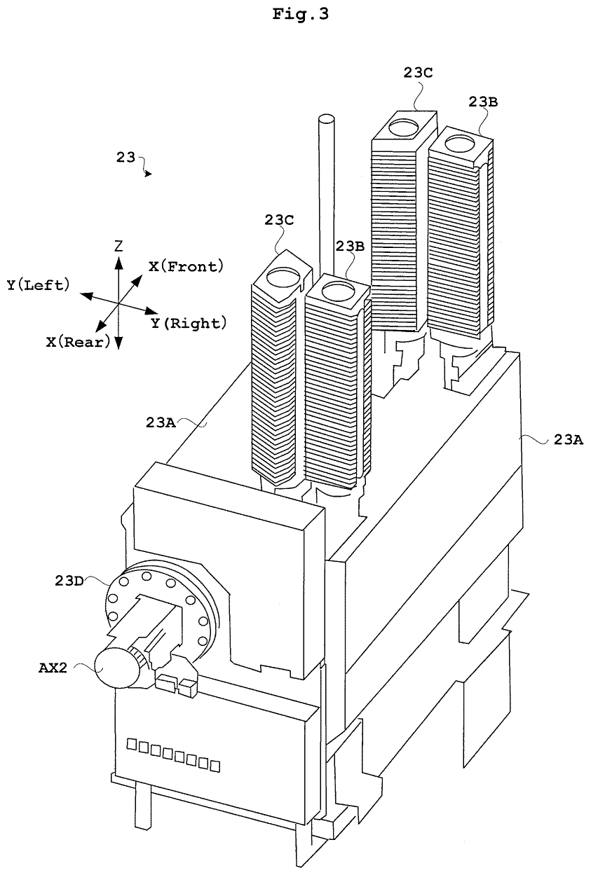

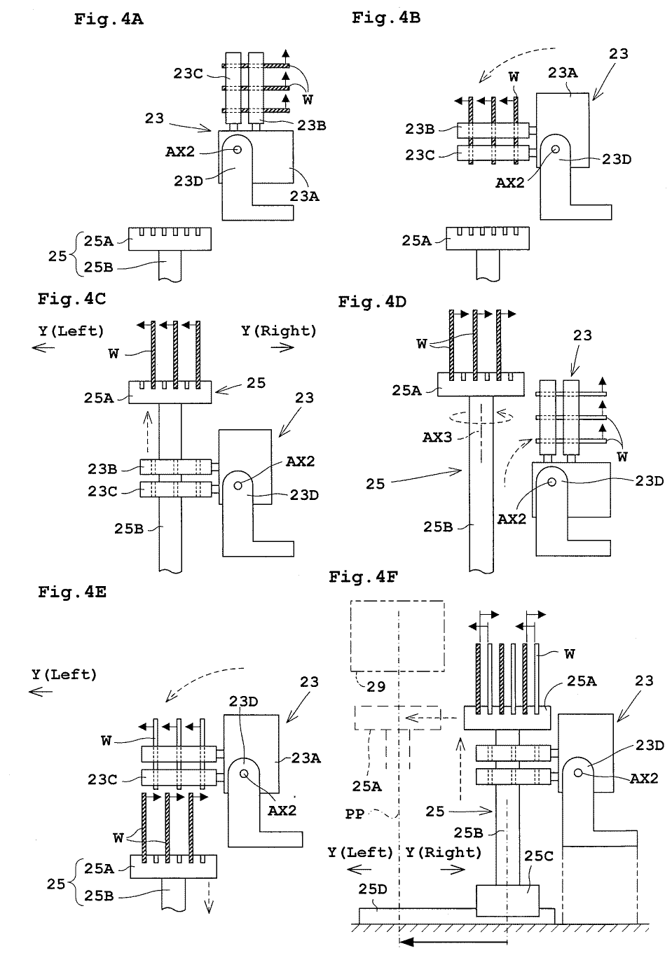

FIG. 3 illustrates the HVC orientation converter 23 of a first embodiment. The HVC orientation converter 23 includes a pair of horizontal holders 23B and a pair of vertical holders 23C extending in the longitudinal direction (Z direction). The support table 23A has a support surface extending in an XY plane to support the horizontal holder 23B and the vertical holder 23C. A rotation drive mechanism 23D is configured to rotate the horizontal holder 23B and the vertical holder 23C by 90° together with the support table 23A. With this rotation, the horizontal holder 23B and the vertical holder 23C are configured to extend in the left-right direction (Y direction). Note that FIGS. 4A to 4F are schematic diagrams for illustrating the operation of the HVC orientation converter 23. Hereinafter, the configuration of each component will be described with reference to FIGS. 3 and 4A to 4F.

The horizontal holder 23B supports the plurality of substrates W in the horizontal orientation from below. That is, the horizontal holder 23B has a comb-shaped structure with a plurality of protrusions corresponding to the substrates W to be supported. Between the adjacent protrusions, there is an elongated recess in which the peripheral edge of the substrate W is located. When the peripheral edge of the substrate W is inserted into the recess, the lower surface of the substrate W in the horizontal orientation comes into contact with the upper surface of the protrusion, and the substrate W is supported in the horizontal orientation.

The vertical holder 23C supports the plurality of substrates W in the vertical orientation from below. That is, the vertical holder 23C has a comb-shaped structure with a plurality of protrusions corresponding to the substrates W to be supported. Between the adjacent protrusions, there is an elongated V-groove in which the peripheral edge of the substrate W is located. When the peripheral edge of the substrate W is inserted into the V-groove, the substrate W is held by the V-groove and supported in the vertical orientation. Since the two vertical holders 23C are provided on the support table 23A, the substrate W is held between different V-grooves at two positions of the peripheral edge.

The pair of horizontal holders 23B and the pair of vertical holders 23C extending in the vertical direction (Z direction) are provided along a virtual circle corresponding to the substrate W in the horizontal orientation to surround the substrate W to be held. The pair of horizontal holders 23B is separated by the diameter of the substrate W, and holds one end of the substrate W and the other end that is the farthest position from the one end. In this manner, the pair of horizontal holders 23B supports the substrate W in the horizontal orientation. On the other hand, the pair of vertical holders 23C is separated by a distance shorter than the diameter of the substrate W, and supports a predetermined portion of the substrate W and a specific portion located near the predetermined portion. In this manner, the pair of vertical holders 23C supports the substrate W in the vertical orientation. The pair of horizontal holders 23B is at the same position in the left-right direction (Y direction), and the pair of vertical holders 23C is at the same position in the left-right direction (Y direction). The pair of vertical holders 23C is provided closer to a side toward which the support table 23A is rotated and tilted (leftward direction) than the pair of horizontal holders 23B.

The rotation drive mechanism 23D supports the support table 23A, enabling its rotation by at least 90° around a horizontal axis AX2 that extends in the front-rear direction (X direction). When the support table 23A in the horizontal state rotates by 90°, the support table 23A becomes the vertical state, and the orientations of the plurality of substrates W held by the horizontal holder 23B and the vertical holder 23C are converted from the horizontal to vertical orientation.

As illustrated in FIG. 4F, the pusher mechanism 25 includes a pusher 25A on which the substrate W in the vertical orientation can be mounted, a lifter/rotator 25B that rotates, lifts, and lowers the pusher 25A, a horizontal mover 25C that moves the lifter/rotator 25B in the left-right direction (Y direction), and a rail 25D that extends in the left-right direction (Y direction) to guide the horizontal mover 25C. The pusher 25A is configured to support a lower portion of each of a plurality of (e.g., 50) substrates W in the vertical orientation. The lifter/rotator 25B is provided below the pusher 25A, and includes an expandable mechanism that lifts and lowers the pusher 25A in the vertical direction. The lifter/rotator 25B can rotate the pusher 25A at least 180° around the vertical axis. The horizontal mover 25C is configured to support the lifter/rotator 25B, and horizontally moves the pusher 25A and the lifter/rotator 25B. The horizontal mover 25C is guided by the rail 25D to enable the pusher 25A to move from the pick-up position closer to the HVC orientation converter 23 to the substrate delivery position PP. The horizontal mover 25C can also shift the substrate W in the vertical orientation by a distance corresponding to the half pitch in the substrate array of the pusher 25A in the array direction of the substrate W.

Here, the operations of the HVC orientation converter 23 and the pusher mechanism 25 will be described. The HVC orientation converter 23 and the pusher mechanism 25 array, for example, a total of 50 substrates W stored in the two carriers C at a predetermined interval (e.g., 5 mm) in a face-to-face manner. The 25 substrates W in the first carrier C are described as first substrates W1 belonging to the first substrate group. Similarly, the 25 substrates W in the second carrier C are described as second substrates W2 belonging to the second substrate group. In FIGS. 4A to 4F for convenience of drawing, the number of first substrates W1 is three, and the number of second substrates W2 is three.

FIG. 4A illustrates a state in which the first substrates W1 in the horizontal orientation are collectively passed to the HVC orientation converter 23 by the first substrate transport mechanism HTR. At this time, the device surface (the surface on which the circuit pattern is formed) of the first substrate W1 faces upward. The 25 first substrates W1 are arranged at predetermined intervals (e.g., 10 mm). The interval of 10 mm is called full pitch (normal pitch). The first substrate W1 in this state is held by the horizontal holder 23B. Note that the pusher 25A at this time is at a pick-up position below the support table 23A.

FIG. 4B illustrates how the support table 23A of the HVC orientation converter 23 is rotated by 90° by the rotation drive mechanism 23D. As described above, in the HVC orientation converter 23, the orientations of the 25 first substrates W1 are converted from the horizontal to vertical orientation. The first substrates W1 in this state are held by the vertical holder 23C.

The pusher mechanism 25 supports a substrate group in the vertical orientation formed by the first orientation conversion mechanism 15 converting the orientations of the first substrates W1 housed in a first carrier C1. FIG. 4C illustrates a state in which the pusher 25A is moved upward from the pick-up position to a position immediately above the pick-up position. This upward movement is performed by the lifter/rotator 25B. As described above, when the pusher 25A moves from the lower side to the upper side of the first substrate W1, the first substrate W1 supported by the vertical holder 23C of the HVC orientation converter 23 is pulled out from the vertical holder 23C and moves onto the pusher 25A. A groove in which the substrate W is held is provided on the upper surface of the pusher 25A. The first substrates W1 are supported by these grooves arrayed at equal intervals. The grooves are arrayed at half pitch and the first substrates W1 are arrayed at full pitch in the HVC orientation converter 23. Thus, the grooves in which the first substrates W1 are held and the empty grooves that support no substrates W are alternately arrayed on the upper surface of the pusher 25A, located immediately above.

FIG. 4D illustrates an operation in which the pusher 25A is rotated by 180° by the lifter/rotator 25B and an operation in which the support table 23A of the HVC orientation converter 23 is reversely rotated by 90° by the rotation drive mechanism 23D. The HVC orientation converter 23 in this state can support the second substrate W2. When the pusher 25A rotates 180°, the substrate W supported at the right end of the pusher 25A moves to the left end of the pusher 25A, and the empty groove located at the left end of the pusher 25A moves to the right end of the pusher 25A. The positional relationship between the HVC orientation converter 23 and the pusher 25A is set so that the substrate W located at the right end of the HVC orientation converter 23 is passed to the right end of the pusher 25A. This enables the HVC orientation converter 23 to pass the second substrate W2 at the right end to the groove at the right end of the pusher 25A regardless of the presence of the first substrate W1 supported by the pusher 25A. The same applies to the other second substrates W2 supported by the HVC orientation converter 23. That is, the second substrates W2, which are arrayed at full-pitch intervals in the HVC orientation converter 23, can be arrayed at full-pitch intervals in order from the right end of the pusher 25A. This is because the empty grooves are arrayed at full-pitch intervals starting from the right end in the pusher 25A after rotation. The first substrate W1 on the pusher 25A at this time fits into the gap between the second substrates W2 arrayed in the pusher 25A. FIG. 4D illustrates how the second substrate W2 has already been transported to the HVC orientation converter 23. In FIG. 4D, the second substrate W2 is supported by the horizontal holder 23B. When the pusher 25A at the position immediately above in the state of FIG. 4D returns to the original pick-up position, the HVC orientation converter 23 can rotate the support table 23A again by 90°.

FIG. 4E illustrates how the support table 23A is actually rotated again. At this time, with the pusher 25A having been rotated by 180°, when the pusher 25A is moved again to the position immediately above as illustrated in FIG. 4F, the second substrate W2 fits into the empty groove sandwiched between the first substrates W1 on the upper surface of the pusher 25A, without interfering with the first substrate W1. In this way, a lot in which the first substrate W1 and the second substrate W2 are alternately arrayed is formed. In FIG. 4E, the second substrate W2 is supported by the vertical holder 23C. Since the lot is configured by arraying the substrates W in a face-to-face manner, the device surfaces of the first substrates W1 constituting the lot all face rightward in FIG. 4F, and the device surfaces of the second substrates W2 all face leftward in FIG. 4F. As described above, the pusher mechanism 25 also supports the substrate group in the vertical orientation formed by the first orientation conversion mechanism 15 converting the orientations of the second substrates W2 housed in the second carrier C2.

FIG. 4F illustrates how the pusher 25A moves to the position immediately above again. Then, the lot generated in the pusher 25A is transported in the left direction (Y direction) by the horizontal mover 25C and moved to the substrate delivery position PP.

In this manner, the pusher mechanism 25 combines the two substrate groups housed in the carrier C at full pitch to form a lot in which the substrates W are arrayed at half pitch. The device surface of the first substrate W1 and the device surface of the second substrate W2 constituting the lot face each other, and the substrates are arrayed in a face-to-face manner.

A dry lot support 33 is provided mainly for the purpose of the temporary standby of a lot batch-assembled by the HVC orientation converter 23 and the pusher mechanism 25. The dry lot support 33 is at a position sandwiched between the substrate delivery position PP and relay apparatus 6 to be described later. When the lot is transported from the dry lot support 33 to the batch processing block 7, the second substrate transport mechanism WTR included in the batch processing apparatus 1 is used.

### 5. Batch Processing Apparatus: Batch Processing Block

The batch processing block 7 is adjacent to the transfer block 5. The batch processing block 7 performs the batch process on the lot described above. The batch processing block 7 is divided into a batch processing region R1 and a collective transport region R2 arrayed in the width direction (Y direction). Each region extends in the front-rear direction (X direction). Specifically, the batch processing region R1 is disposed inside the batch processing block 7. The collective transport region R2 is adjacent to the batch processing region R1 and is disposed on the leftmost side of the batch processing block 7.

### <5.1. Batch Processing Region>

The batch processing region R1 in the batch processing block 7 is a rectangular region extending in the front-rear direction (X direction). One end side (front side) of the batch processing region R1 is adjacent to the relay apparatus 6. The other end side of the batch processing region R1 extends in a direction (rear side) away from the transfer block 5 and the relay apparatus 6. Therefore, the relay apparatus 6 is an apparatus that is inserted at a position where the batch processing apparatus 1 is divided from the middle. When a lot is transported from the batch processing apparatus 1 to the relay apparatus 6, the second substrate transport mechanism WTR included in the batch processing apparatus 1 is used.

The second substrate transport mechanism WTR collectively transports a plurality of substrates W in the vertical orientation among the transfer block 5, the batch processing units BPU1 to BPU6, and a loading position IP of the relay apparatus 6. Thus, the collective transport region R2, which is a region where the second substrate transport mechanism WTR can move, is not divided by the relay apparatus 6 and extends in the Y direction along the left end of the relay apparatus 6. The relay apparatus 6 is configured to be fitted inside the batch processing apparatus 1, but does not reach the left end of the batch processing apparatus 1. This is because the collective transport region R2 is provided at the left end of the batch processing apparatus 1.

The batch processing region R1 includes a batch-type processing part that mainly performs the batch-type process. Specifically, the batch processing region R1 has an array of a batch drying chamber DC for collectively drying a plurality of substrates W, and a plurality of batch processing units BPU1 to BPU6 for collectively performing an immersion process on the plurality of substrates W in a direction in which the batch processing region R1 extends. The batch processing units BPU1 to BPU6 collectively perform the immersion process on a plurality of substrates in the vertical orientation. The array of the batch drying chamber DC and the batch processing units BPU1 to BPU6 will be specifically described. The batch drying chamber DC is adjacent to the relay apparatus 6 from the rear. The first batch processing unit BPU1 is adjacent to the batch drying chamber DC from the rear. The second batch processing unit BPU2 is adjacent to the first batch processing unit BPU1 from the rear. The third batch processing unit BPU3 is adjacent to the second batch processing unit BPU2 from the rear. The fourth batch processing unit BPU4 is adjacent to the third batch processing unit BPU3 from the rear. The fifth batch processing unit BPU5 is adjacent to the fourth batch processing unit BPU4 from the rear. The sixth batch processing unit BPU6 is adjacent to the fifth batch processing unit BPU5 from the rear. Therefore, the batch drying chamber DC, the first batch processing unit BPU1, the second batch processing unit BPU2, the third batch processing unit BPU3, the fourth batch processing unit BPU4, the fifth batch processing unit BPU5, and the sixth batch processing unit BPU6 are arranged to be separated from the relay apparatus 6 in this order. In FIG. 1, the second batch processing unit BPU2 to the fifth batch processing unit BPU5 are omitted for convenience of drawing. This configuration can be understood by referring to FIG. 2. The batch processing units BPU1 to BPU6 correspond to a batch processing tank of the present invention.

Specifically, the second batch processing unit BPU2 includes a batch chemical treatment tank CHB2 that collectively performs chemical treatment on lots, and a lifter LF2 that lifts and lowers the lots between a substrate delivery position and a chemical treatment position (cf. FIG. 2). The substrate delivery position is a position set above the batch chemical treatment tank CHB2 accessible by the second substrate transport mechanism WTR, and the chemical treatment position is a position set in the batch chemical treatment tank CHB2 where the lot can be immersed in a chemical solution. The batch chemical treatment tank CHB2 performs acid treatment on the lot. The acid treatment may be a phosphoric acid treatment, but may be a treatment using another acid. In the phosphoric acid treatment, etching treatment is performed on a plurality of substrates W constituting a lot. In the etching treatment, for example, the nitride film on the surface of the substrate W is chemically etched.

The batch chemical treatment tank CHB2 stores an acid solution such as a phosphoric acid solution. The batch chemical treatment tank CHB2 is provided with a lifter LF2 that moves the lot up and down. The batch chemical treatment tank CHB2 supplies, for example, a chemical solution upward from below for the convection of the chemical solution. The lifter LF2 is lifted and lowered in the vertical direction (Z direction). Specifically, the lifter LF2 is lifted and lowered between a processing position that corresponds to the inside of the batch chemical treatment tank CHB2 and a delivery position that corresponds to an upper side of the batch chemical treatment tank CHB2. The lifter LF2 holds a lot including the substrate W in the vertical orientation. The lifter LF2 delivers the lot to and from the second substrate transport mechanism WTR at the delivery position. When the lifter LF2 is lowered from the delivery position to the processing position while holding the lot, the entire region of the substrate W is located below the liquid surface of the chemical solution. When the lifter LF2 is lifted from the processing position to the delivery position while holding the lot, the entire region of the substrate W is located above the liquid surface of the chemical solution.

Specifically, the third batch processing unit BPU3 includes a batch chemical treatment tank CHB3 and a lifter LF3 that lifts and lowers the lot between the substrate delivery position and the chemical treatment position. The batch chemical treatment tank CHB3 has a configuration similar to that of the batch chemical treatment tank CHB2 described above. That is, the batch chemical treatment tank CHB3 stores the chemical solution described above, and is provided with the lifter LF3. The batch chemical treatment tank CHB3 performs the same treatment as the batch chemical treatment tank CHB2 on the lot. The batch processing apparatus 1 of the present embodiment includes a plurality of processing tanks capable of performing the same chemical treatment. This is because the phosphoric acid treatment takes more time than other treatments. The phosphoric acid treatment requires a long time (e.g., 60 minutes). Thus, in the apparatus of the present embodiment, the acid treatment can be performed in parallel by a plurality of batch chemical treatment tanks.

The fourth batch processing unit BPU4 to the sixth batch processing unit BPU6 have configurations similar to those of the second batch processing unit BPU2 and the third batch processing unit BPU3. That is, the fourth batch processing unit BPU4 includes the batch chemical treatment tank CHB4 and a lifter LF4 that lifts and lowers the lot between the substrate delivery position and the chemical treatment position. Similarly, the fifth batch processing unit BPU5 includes the batch chemical treatment tank CHB5 and a lifter LF5 that lifts and lowers the lot between the substrate delivery position and the chemical treatment position. The sixth batch processing unit BPU6 includes a batch chemical treatment tank CHB6 and a lifter LF6 that lifts and lowers the lot between the substrate delivery position and the chemical treatment position. Therefore, the lot is acid-treated in one of the batch chemical treatment tank CHB2 to the batch chemical treatment tank CHB6. When the chemical treatment is performed in parallel by the five treatment units in this manner, the throughput of the apparatus is increased.

Specifically, the first batch processing unit BPU1 includes a batch rinse processing tank ONB that stores a rinse liquid, and a lifter LF1 that lifts and lowers the lot between the substrate delivery position and the rinse position. The substrate delivery position is a position set above the batch rinse processing tank ONB accessible by the second substrate transport mechanism WTR, and the rinse position is a position set in the batch rinse processing tank ONB where the lot can be immersed in the rinse liquid. The batch rinse processing tank ONB has a configuration similar to that of the batch chemical treatment tank CHB2 described above. That is, the batch rinse processing tank ONB stores the rinse solution and is provided with the lifter LF1. Unlike other processing tanks, the batch rinse processing tank ONB stores pure water, and is provided for the purpose of cleaning the chemical solution adhering to the plurality of substrates W. In the batch rinse processing tank ONB, when the specific resistance of the pure water in the tank increases to a predetermined value, the cleaning process is completed.

As described above, the batch rinse processing tank ONB in the present embodiment is located closer to the relay apparatus 6 than the batch chemical treatment tanks CHB2 to CHB6. With such a configuration, the mechanisms constituting the relay apparatus 6 and the batch chemical treatment tank CHB2 to the batch chemical treatment tank CHB6 are separated as much as possible, so that the relay apparatus 6 is not adversely affected by an acid such as phosphoric acid. By arranging the relay apparatus 6 and the batch rinse processing tank ONB close to each other, the lot that have completed the rinse process is transported by a short distance and immediately loaded into the relay apparatus 6. Therefore, according to the configuration of the present embodiment, the transport of the substrate W can be promptly completed while the substrate W is held in a wet state.

### <5.2. Collective Transport Region>

The collective transport region R2 in the batch processing block 7 is a rectangular region extending in the front-rear direction (X direction). The collective transport region R2 is provided along the outer edge of the batch processing region R1, and has one end side extending to the transfer block 5 and the other end side extending in a direction away from the transfer block 5. Thus, the collective transport region R2 also has a configuration along the relay apparatus 6 at a position sandwiched between the transfer block 5 and the batch processing block 7.

In the collective transport region R2, the second substrate transport mechanism WTR for collectively transporting a plurality of substrates W is provided. The second substrate transport mechanism WTR collectively transports a plurality of substrates W (specifically, a lot) among the substrate delivery position PP defined in the transfer block 5, the dry lot support 33, the batch drying chamber DC, each of the batch processing units BPU1 to BPU6, and the loading position IP in the relay apparatus 6 to be described later. The second substrate transport mechanism WTR is configured to be able to reciprocate in the front-rear direction (X direction) over the transfer block 5, the relay apparatus 6, and the batch processing block 7. In addition to the collective transport region R2 in the batch processing block 7, the second substrate transport mechanism WTR is movable to the substrate delivery position PP in the transfer block 5, the dry lot support 33, and the loading position IP in the relay apparatus 6.

The second substrate transport mechanism WTR includes a pair of chucks 29 that transport a lot. The pair of chucks 29 can change between a closed state in which the chucks are close to each other and an open state in which the chucks are separated from each other. The chuck 29 is a member extending in the Y direction in which grooves for gripping the substrates W are arrayed at half pitch. The pair of chucks 29 enters the closed state to receive a plurality of substrates W constituting a lot. Then, the pair of chucks 29 enters the open state to pass the plurality of substrates W constituting the lot to another member (the lifter LF1, etc.). The second substrate transport mechanism WTR delivers the lot to and from the substrate delivery position PP in the transfer block 5, the dry lot support 33, and a lifter LF65 belonging to a lot standby tank 65 provided at the loading position IP in the relay apparatus 6. In addition, the second substrate transport mechanism WTR delivers the lot to and from each of the lifters LF1 to LF6 belonging to the batch processing units BPU1 to BPU6 in the batch processing block 7 and the batch drying chamber DC.

The collective transport region R2 is equipped with a guide rail 31X extending in the X direction to guide the second substrate transport mechanism WTR. The second substrate transport mechanism WTR is movable forward and backward in the X direction along the guide rail 31X. Thus, the guide rail 31X extends from the batch processing block 7 to the transfer block 5 via the relay apparatus 6. More specifically, the guide rail 31X faces the substrate delivery position PP in the transfer block 5 from the Y direction, and faces the sixth batch processing unit BPU6 in the batch processing block 7 from the Y direction. In addition, the guide rail 31X faces the dry lot support 33 in the transfer block 5, the lot standby tank 65 in the relay apparatus 6, the batch drying chamber DC in the batch processing block 7, and the first batch processing unit BPU1 to the sixth batch processing unit BPU6 from the Y direction.

### <5.3. Other Configurations>

The batch drying chamber DC is disposed at a position sandwiched between the first batch processing unit BPU1 and the relay apparatus 6. The batch drying chamber DC includes a drying chamber that stores a lot in which the substrates W in the vertical orientation are arrayed. The drying chamber includes an inert gas supply nozzle that supplies an inert gas into the chamber and a vapor supply nozzle that supplies vapor of an organic solvent into the tank. The batch drying chamber DC first supplies an inert gas to the lot supported in the chamber to replace the atmosphere in the chamber with the inert gas. Then, pressure reduction in the chamber is started. In a state where the inside of the chamber is depressurized, the vapor of the organic solvent is supplied into the chamber. The organic solvent is discharged to the outside of the chamber together with moisture adhering to the substrate W. In this way, the batch drying chamber DC performs the drying of the lot. The inert gas at this time may be, for example, nitrogen, and the organic solvent may be, for example, isopropyl alcohol (IPA). In the present embodiment, the substrate W is dried by the single-wafer processing apparatus 2 without using the batch drying chamber DC. The batch drying chamber DC is configured to be used when the batch processing apparatus 1 alone performs the substrate process. In this case, the lot, which has completed the batch rinse process in the batch rinse processing tank ONB, is subjected to the drying process in the batch drying chamber DC without being moved to the relay apparatus 6, and is then transported to the substrate delivery position PP. Such lot transport is performed by the second substrate transport mechanism WTR. Thereafter, the lot is divided into the array of the first substrates W1 and the array of the second substrates W2 following the reverse path to the description of FIG. 4. The array of the first substrates W1 is returned to the empty carrier C by the first substrate transport mechanism HTR, and the array of the second substrates W2 is then returned to the empty carrier C by the first substrate transport mechanism HTR.

### 6. Relay Apparatus

The relay apparatus 6 is configured to bridge the batch processing apparatus 1 and the single-wafer processing apparatus 2, and has a left end fitted into the batch processing apparatus 1 and a right end fitted into the single-wafer processing apparatus 2. The relay apparatus 6 includes the transport path of the substrate W extending in the Y direction to connect the collective transport region R2 of the batch processing apparatus 1 to a sheet transport region R3 of the single-wafer processing apparatus 2. The transport path transports the substrate W in the Y direction (horizontal) without changing the position of the substrate W in the Z direction. Therefore, the insertion position of the relay apparatus 6 in the batch processing apparatus 1 and the insertion position of the relay apparatus 6 in the single-wafer processing apparatus 2 are at the same position in the Z direction.

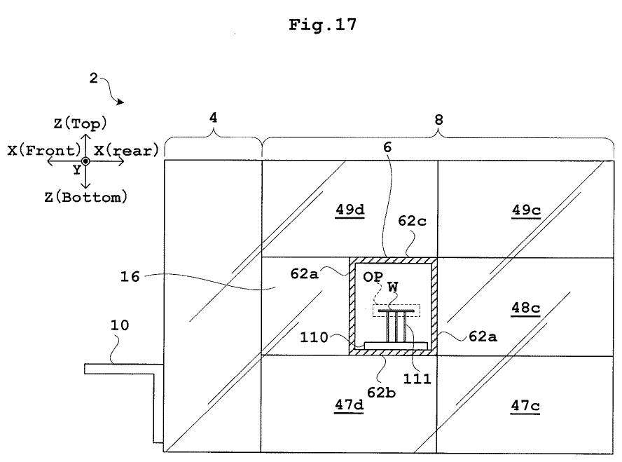

The relay apparatus 6 is located in the middle layer of the batch processing apparatus 1 and the single-wafer processing apparatus 2 (cf. FIG. 17). Therefore, the relay apparatus 6 bridges the batch processing apparatus 1 and the single-wafer processing apparatus 2 at an aerial position away from the floor surface on which the batch processing apparatus 1 and the single-wafer processing apparatus 2 are installed. The specific position of the relay apparatus 6 is related to the structure of the single-wafer processing apparatus 2, and hence the specific position will be described in detail in accordance with the description of the single-wafer processing apparatus 2.

The relay apparatus 6 includes a relay casing 6A that couples the first casing 1A related to the batch processing apparatus 1 and the second casing 2A related to the single-wafer processing apparatus 2 separated from each other in the Y direction. The relay casing 6A is provided between a third wall surface 1B facing the second casing 2A among wall surfaces constituting the first casing 1A and a fourth wall surface 2B facing the third wall surface 1B among wall surfaces constituting the second casing 2A.

The relay casing 6A includes a side wall 62a, a bottom plate 62b, and a top plate 62c that couple the batch processing apparatus 1 and the single-wafer processing apparatus 2. The configurations of the side wall 62a, the bottom plate 62b, and the top plate 62c are detailed in FIGS. 2 and 17. The relay casing 6A couples the casings included in the batch processing apparatus 1 and the single-wafer processing apparatus 2 to constitute one substrate processing system. The substrate processing system is thus configured to isolate the outside air and the atmosphere in the apparatus.

The relay apparatus 6 includes a lot standby tank 65 that holds a batch-processed lot on standby in pure water, an underwater orientation converter 55 that receives a plurality of substrates W arrayed in the Y direction and collectively rotates the received substrates W by 90° in the water to convert the orientations of the plurality of substrates W from the vertical to horizontal orientation, a relay transport mechanism OTR that transports the substrates W in the horizontal orientation one by one to an unloading position OP, and a rotation adjustment mechanism SRM that adjusts the orientations of the substrates W. The lot standby tank 65, the underwater orientation converter 55, the relay transport mechanism OTR, and the rotation adjustment mechanism SRM are arrayed in this order in the right direction starting from the left portion of the batch processing apparatus 1. Hereinafter, each component will be specifically described. Note that the underwater orientation converter 55 corresponds to an orientation conversion mechanism of the present invention.

### <6.1. Relay Apparatus: Lot Standby Tank>

The lot standby tank 65 immerses the batch-processed lot in pure water. The lot standby tank 65 has a configuration similar to that of the first batch processing unit BPU1 included in the batch processing apparatus 1. That is, the lot standby tank 65 includes the lifter LF65 that holds pure water and lifts and lowers the lot. The lifter LF65 can reciprocate between a loading position IP for loading a lot into the relay apparatus 6 and an immersion position for immersing the loaded lot in pure water. The loading position IP is a position determined for receiving the batch-processed substrate from the batch processing apparatus 1. The loading position IP is located above the immersion position and is a position where the second substrate transport mechanism WTR can transport the substrate. The loading position IP is set so that the entire region of the substrate W constituting the lot is in the air, and the immersion position is set so that the entire region of the substrate W constituting the lot is immersed in pure water.

### <6.2. Relay Apparatus: Full-Pitch Array Substrate Transport Mechanism>

The full-pitch array substrate transport mechanism STR sorts the lot immersed in the lot standby tank 65 into the first substrates W1 and the second substrates W2. The full-pitch array substrate transport mechanism STR can transport 25 substrates W arrayed at full pitch between the lot standby tank 65 and the underwater orientation converter 55. In the lot standby tank 65, substrates W arrayed at half pitch are on standby, and the full-pitch array substrate transport mechanism STR picks up substrates, which are a half of the 50 substrates W, and transports the 25 substrates W to the underwater orientation converter 55. The full-pitch array substrate transport mechanism STR includes a pair of chucks 30 similar to the pair of chucks 29 in the second substrate transport mechanism WTR. Similarly to the chuck 29, the chuck 30 has grooves formed at half-pitch intervals, but is different from the chuck 29 in that two types of grooves are alternately arrayed. That is, in the chuck 30, deep grooves that cannot grip the substrates W and shallow grooves that grip the substrates W are alternately arrayed at half-pitch intervals. Therefore, when the full-pitch array substrate transport mechanism STR tries to grip the lot in lifter LF65, 25 substrates W are picked up by the shallow grooves that can grip the substrates W, and the remaining 25 substrates W cannot come into contact with the deep grooves and remain in the lifter LF65. The shallow grooves in the chuck 30 are arrayed at twice the pitch of the half pitch (full pitch), and hence the full-pitch array substrate transport mechanism STR picks up 25 substrates W arrayed at full pitch from the lot in the lifter LF65. Since the lot is configured by arraying the substrates W in a face-to-face manner, the picked-up substrates W are arrayed such that the front surface (device surface) is on the right side and the back surface is on the left side to prevent the device surfaces of the adjacent substrates W from facing each other. On the other hand, the 25 substrates W that are not picked up and remain in the lifter LF65 are arrayed such that the front surface (device surface) is on the left side and the back surface is on the right side to prevent the device surfaces of the adjacent substrates W from facing each other. The full-pitch array substrate transport mechanism STR corresponds to a substrate group sorting mechanism of the present invention.

Similarly to the chucks 29 of the second substrate transport mechanism WTR, the pair of chucks 30 included in the full-pitch array substrate transport mechanism STR can take two states: a closed state in which the chucks 30 are close to each other in the X direction, and an open state in which the chucks 30 are separated from each other in the X direction. When the pair of chucks 30 is in the closed state, the chucks 30 are sufficiently close to each other with respect to the diameter of the substrate W, and hence two places in the lower portion of the substrate W come into contact with the chucks 30, respectively. In this way, the substrate W is gripped by the pair of chucks 30. When the pair of chucks 30 that has been in the closed state enters the open state, the substrate W is separated from the chucks 30 because the chucks 30 are sufficiently far apart with respect to the diameter of the substrate W. Specifically, the pair of chucks 30 enters the open state in the following cases: before receiving the plurality of substrates W from the lifter LF65 at the loading position IP, and after passing the substrates W to the pusher 55A, which and the immersion tank will be described later, at a position above the immersion tank.

The relay apparatus 6 incudes a guide rail 31Y extending in the Y direction to guide the full-pitch array substrate transport mechanism STR. The full-pitch array substrate transport mechanism STR is movable forward and backward in the Y direction along the guide rail 31Y. Thus, the guide rail 31Y extends from the lot standby tank 65 to the underwater orientation converter 55.

The full-pitch array substrate transport mechanism STR can move forward and backward in the Y direction from a loading position IP, which is a position where the full-pitch array substrate transport mechanism STR is guided by the guide rail 31Y and a lot is delivered from the lifters LF65, to the position above the immersion tank where the pusher 55A to be described later, included in the underwater orientation converter 55, receives a plurality of substrates W. As a result, the full-pitch array substrate transport mechanism STR can transport the plurality of substrates W in the Y direction from the loading position IP to the position above the immersion tank. Further, when the second substrate transport mechanism WTR moves from the transfer block 5 to the batch processing block 7, the full-pitch array substrate transport mechanism STR can move to the position above the immersion tank so as not to interfere with the second substrate transport mechanism WTR (cf. FIG. 2).

### <6.3. Relay Apparatus: Underwater Converter>

The underwater orientation converter 55 converts the plurality of substrates W, received from the batch processing apparatus 1, from the vertical to horizontal orientation. The underwater orientation converter 55 collectively converts the sorted first substrate W1 and second substrate W2 from the vertical to horizontal orientation. The underwater orientation converter 55 includes an immersion tank 73 that holds pure water, inversion chucks 71 located above the immersion tank 73, and a pair of inversion chuck support mechanisms 72 that hold the respective inversion chucks 71 and lift and rotate the inversion chucks 71. The inversion chucks 71 can be lifted and lowered from a substrate delivery position with the full-pitch array substrate transport mechanism STR, set above the liquid surface of the immersion tank 73, to the liquid in the immersion tank 73. The inversion chucks 71 immerse the plurality of substrates W received from the full-pitch array substrate transport mechanism STR in the immersion tank 73, and can rotate 90° in one direction or in the opposite direction in that state. The orientations of the plurality of substrates W in the vertical orientation are converted into the horizontal orientation by the rotation of the pair of inversion chucks 71.

The operation of the pair of inversion chuck support mechanisms 72 enables the inversion chucks 71 to change between a closed state in which the plurality of substrates W can be held and an open state in which the plurality of held substrates W are opened. The inversion chucks 71 can be rotated by 90° in one direction and the opposite direction while maintaining the mutual positional relationship by the operation of the pair of inversion chuck support mechanisms 72. Then, the inversion chucks 71 can be lifted and lowered from above the immersion tank 73 to the inside of the immersion tank 73 while the mutual positional relationship is maintained by the operation of the pair of inversion chuck support mechanisms 72.

The inversion chuck 71 has a comb shape in which a plurality of V-grooves 71a are provided at full-pitch intervals, and the pair of inversion chucks 71 holds the plurality of substrates W from both sides by fitting the plurality of substrates W into the V-grooves. When the inversion chucks 71 are in the closed state, each of the substrate ends comes into contact with the deepest portion of the V-groove, and even if the inversion chucks 71 are rotated in this state, the substrate W does not slide off the inversion chucks 71. When the inversion chucks 71 are in the open state, the substrate W can be received from the full-pitch array substrate transport mechanism STR that holds the plurality of substrates W on standby above the immersion tank 73. Further, the inversion chucks 71 can take a state between the closed state and the open state (half-open state), and this state will be described later.

### <6.4. Relay Apparatus: Relay Transport Mechanism>

The relay transport mechanism OTR is a mechanism provided between the loading position IP and the unloading position OP, receives the substrates W in the horizontal orientation one by one from the underwater orientation converter 55, and transports the substrates W to the unloading position OP along the substrate transport path. As illustrated in FIG. 1, the relay transport mechanism OTR is guided by a relay rail 32Y extending in the Y direction from the underwater orientation converter 55 to the rotation adjustment mechanism SRM to be described later, and can move in the Y direction. The relay transport mechanism OTR includes a hand 103. The relay transport mechanism OTR can receive the substrates W in the horizontal orientation one by one from the inversion chucks 71 with the hand 103 facing the underwater orientation converter 55. The relay transport mechanism OTR can transport the substrate to the unloading position OP of the rotation adjustment mechanism SRM with an arm.

### <6.5. Relay Apparatus: Operation of Relay Transport Mechanism>

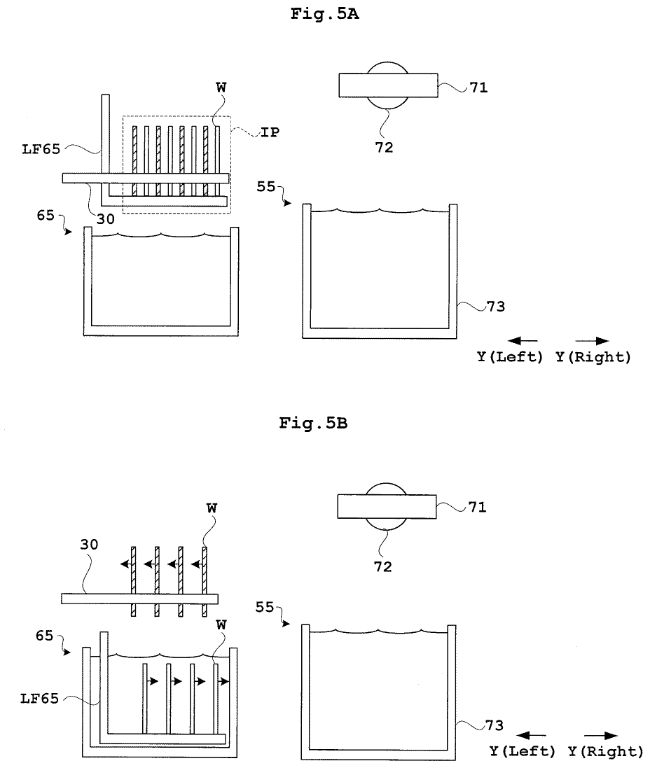

A description will be given of how the relay apparatus 6 transports the substrate W at the loading position IP to the unloading position OP. The unloading position OP is a position determined for passing the substrate W, received at the loading position IP, to the single-wafer processing apparatus 2. FIG. 5A illustrates how the lifter LF65 holds a plurality of substrates W at the loading position IP set above the lot standby tank 65. The second substrate transport mechanism WTR transports the substrate to the loading position IP. The plurality of substrates W placed on the lifter LF65 are arrayed in a face-to-face manner in which the substrates W with the device surfaces facing rightward and the substrates W with the device surfaces facing leftward are alternately arrayed.

At this time, when the lifter LF65 is lowered from the loading position IP to the immersion position, it is possible to prevent the substrates W on standby for transport from being dried while the substrates W are transported one by one in the relay apparatus 6.

FIG. 5A illustrates how the plurality of substrates W are collectively passed from the lifter LF65 to the full-pitch array substrate transport mechanism STR to transport the plurality of substrates W to the underwater orientation converter 55. The lifter LF65 at this time supports the plurality of substrates W at the loading position IP, and the full-pitch array substrate transport mechanism STR moves the pair of chucks 30 to a position where the lot can be held, and closes the chucks 30. At this time, as described above, the chucks 30 can grip only half of the plurality of substrates W arrayed at half pitch constituting the lot. As a result, in the lot, the substrates W held by the chucks 30 and the substrates W not held by the chucks 30 are alternately arrayed.

FIG. 5B illustrates how the lifter LF65 is then lowered from the loading position IP to the immersion position. When the lifter LF65 is lowered from the state of FIG. 5A, a plurality of substrates W arrayed at full pitch corresponding to the half of the substrates W constituting the lot remain in the full-pitch array substrate transport mechanism STR, and the remaining half of the substrates W are returned to the lot standby tank 65 while arrayed at full pitch in the lifter LF65. The device surfaces of the plurality of substrates W remaining in the full-pitch array substrate transport mechanism STR face rightward, and the device surfaces of the plurality of substrates W held at the immersion position by the lifter LF65 face leftward.

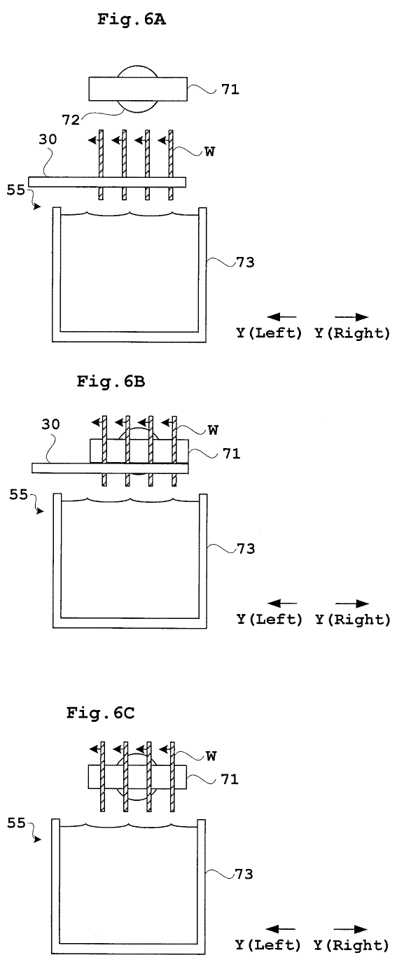

FIG. 6A illustrates how the full-pitch array substrate transport mechanism STR then transports the plurality of substrates W to the position above the immersion tank 73. At this time, the pair of inversion chucks 71 is located above the full-pitch array substrate transport mechanism STR, and the rotation angle is 0° in the initial state. The inversion chucks 71 in the initial state expand in the horizontal direction and can receive a plurality of substrates W in the vertical orientation.

FIG. 6B illustrates how the inversion chucks 71 have then been lowered to the full-pitch array substrate transport mechanism STR. The operation of the inversion chucks 71 is implemented by the inversion chuck support mechanism 72. FIG. 6B illustrates how 25 substrates W are passed from the chucks 30 of the full-pitch array substrate transport mechanism STR to the inversion chucks 71. That is, the pair of inversion chucks 71 maintain the open state, are lowered to the full-pitch array substrate transport mechanism STR, and then enter the closed state. The pair of inversion chucks 71 in the open state is separated only enough to allow the passage of the substrate W, and hence the inversion chucks 71 can approach the chucks 30 without contacting the substrate W. Thereafter, the inversion chucks 71 enter the closed state by the operation of the inversion chuck support mechanism 72, and grip the 25 substrates W. The 25 substrates W at this time are gripped by both the chucks 30 and the inversion chucks 71. Thereafter, the chucks 30 enter the open state and retract in the Y direction (left direction). In this manner, the delivery of the substrate W from the chucks 30 to the inversion chucks 71 is executed. FIG. 6C illustrates a state in which 25 the substrates W have been passed to the inversion chucks 71. As indicated by an arrow in FIG. 6C, the inversion chucks 71 are lowered to below the liquid surface of the immersion tank 73, and immerse the 25 substrates W in pure water held in the immersion tank 73.

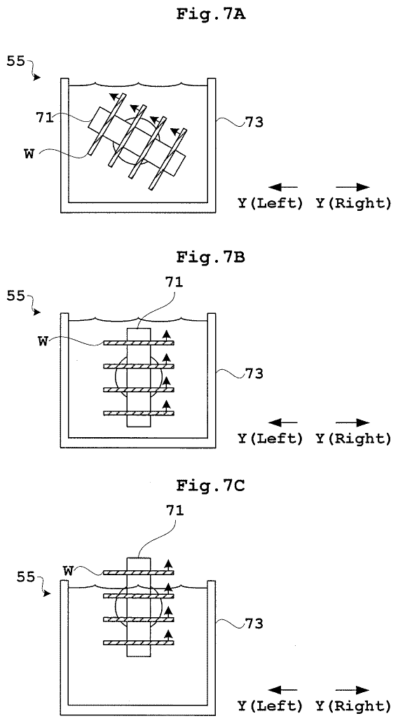

FIG. 7A shows how the inversion chucks 71 are then rotating by 90° while the 25 substrates W are immersed in pure water. The operation of the inversion chucks 71 is implemented by the inversion chuck support mechanism 72. FIG. 7B illustrates how the inversion chucks 71 have completed the rotation of 90°. In this manner, the device surfaces of the 25 substrates W immersed in the immersion tank 73 and facing the Y direction (left direction) are rotated by 90° and face upward. When the substrate W is tilted in this manner, the orientation of the substrate W can be set to the horizontal orientation with the device surface facing upward. From this point forward, the substrate W in the horizontal orientation is transported with the device surface facing upward.

FIG. 7C illustrates how the inversion chucks 71 then move one of the 25 substrates W above the liquid surface of the immersion tank 73. The operation of the inversion chucks 71 is implemented by the inversion chuck support mechanism 72. According to FIG. 7C, there is only one substrate W above the liquid surface, and the remaining 24 substrates W are under the liquid surface in the immersion tank 73. With such a configuration, the 24 substrates W are not dried during standby for transport. One substrate W above the liquid surface is transported to the unloading position OP by the relay transport mechanism OTR while maintaining the horizontal orientation. Thereafter, the inversion chuck support mechanism 72 lifts the pair of inversion chucks 71 by a height corresponding to the full pitch every time the relay transport mechanism OTR transports the substrate W. When this operation is repeated, all of the 25 substrates W are transported to the unloading position OP by the relay transport mechanism OTR.

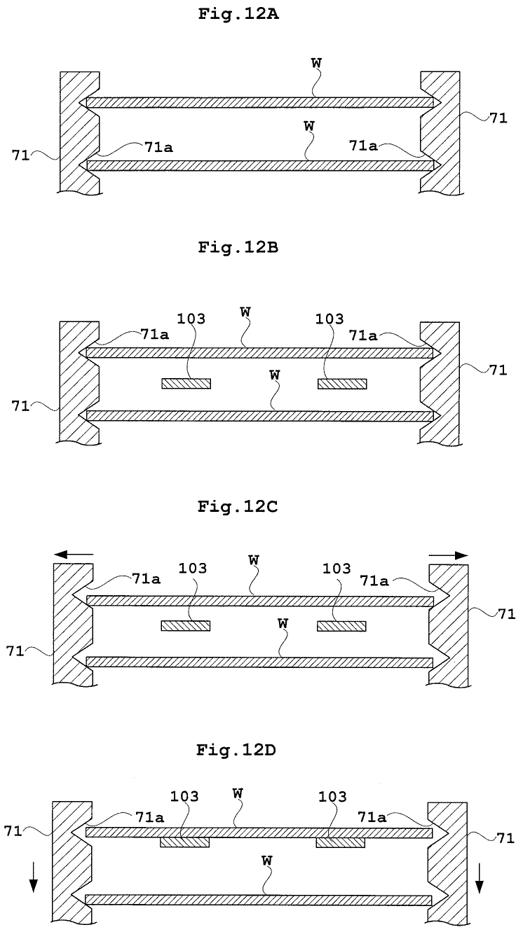

The opening and closing operation of the inversion chucks 71 in each state of FIGS. 5A to 7C will be described. As described above, the pair of inversion chucks 71 in each of the states of FIGS. 5A to 6A is in the open state, being unable to grip the substrate W. Since the inversion chucks 71 in the open state can pass through the substrate W, the inversion chucks 71 can move to the position illustrated in FIG. 6B without colliding with the substrate W. In FIG. 6B, the pair of inversion chucks 71 is switched from the open state to the closed state. At this time, the V-grooves included in each of the pair of inversion chucks 71 cause the respective ends of the 25 substrates W, arrayed at full pitch, to enter and come into contact. Since the V-grooves are arrayed at full pitch, the 25 substrates W arrayed at full pitch easily fit into the respective V-grooves. How the substrate W fits into each V-groove will be described in detail in FIG. 12A. The pair of inversion chucks 71 in FIGS. 6C to 7B is in the closed state, gripping the substrate W. In this state, even if the inversion chucks 71 are rotated, the substrate W to be gripped is not dropped.

To realize the state of FIG. 7C, it is necessary to devise to prevent the substrate W on standby in the immersion tank 73 from dropping while allowing the relay transport mechanism OTR to transport the substrate W. Therefore, according to the present embodiment, in the state of FIG. 7C, the pair of inversion chucks 71 is brought into a half-open state. This can realize a state in which the substrate W is supported so as to be extracted. The half-open state will be described in detail in FIGS. 12C and 12D.

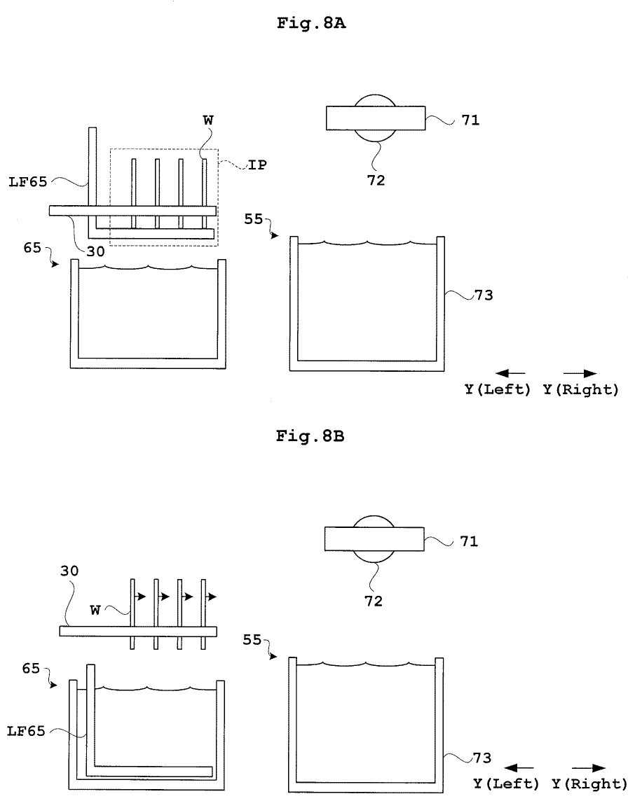

FIG. 8A illustrates how the lifter LF65 then holds the plurality of substrates W at the loading position IP set above the lot standby tank 65. The second substrate transport mechanism WTR transports the substrate to the loading position IP. In the 25 substrates W placed on the lifter LF65, the substrates W with their device surfaces facing rightward are arrayed at full pitch. These substrates W are the substrates W left in the lot standby tank 65 in FIG. 5B. How these 25 substrates W are transported will be described below with reference to FIG. 8A and subsequent figures. Note that FIG. 8A illustrates how the substrate transport in the horizontal orientation described in FIG. 7C is completed and the pair of inversion chucks 71 returns to the initial state illustrated in FIG. 5A. The pair of inversion chucks 71 in the initial state can expand in the Y direction to introduce the substrate W in the vertical orientation, and is located above the immersion tank 73.

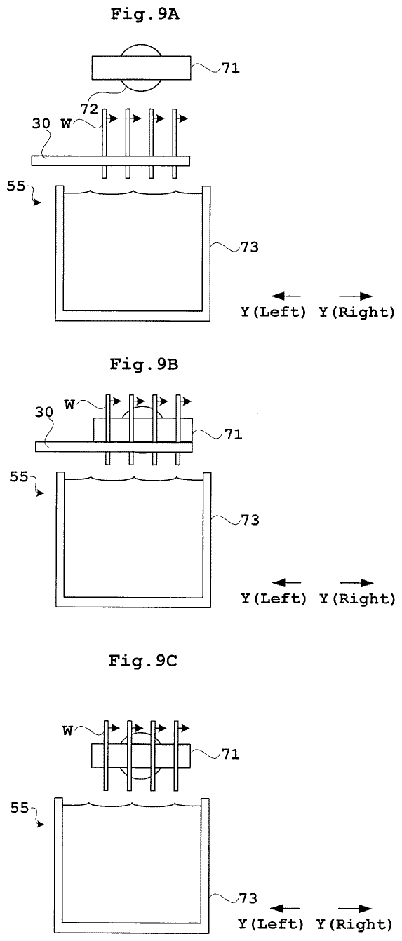

FIG. 8B is a view corresponding to FIG. 5B described above, and illustrates how 25 substrates W have been passed to the chucks 30 of the full-pitch array substrate transport mechanism STR. FIG. 9A is a view corresponding to FIG. 6A described above, and illustrates how the full-pitch array substrate transport mechanism STR moves 25 substrates W to a position sandwiched between the immersion tank 73 and the pair of inversion chucks 71. FIG. 9B is a view corresponding to FIG. 6B described above, and illustrates how the 25 substrates W are passed from the full-pitch array substrate transport mechanism STR to the pair of inversion chucks 71. FIG. 9C is a view corresponding to FIG. 6C described above, and illustrates how the 25 substrates W supported by the pair of inversion chucks 71 are above the immersion tank 73.

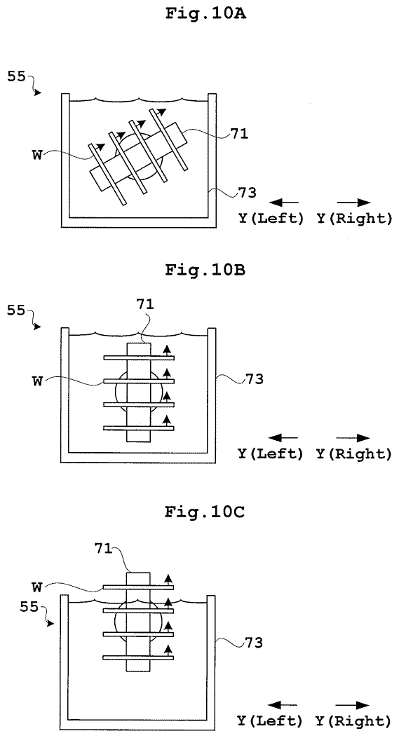

FIG. 10A illustrates how the inversion chucks 71 are then rotating by −90° in a state where the 25 substrates W are immersed in pure water. The operation of the inversion chucks 71 is implemented by the inversion chuck support mechanism 72. FIG. 10B illustrates how the inversion chucks 71 have completed the rotation of −90°. In this manner, the device surfaces of the 25 substrates W immersed in the immersion tank 73 and facing the Y direction (right direction) are rotated by 90° and face upward. When the substrate W is tilted in this manner, the orientation of the substrate W can be set to the horizontal orientation with the device surface facing upward. From this point forward, the substrate W in the horizontal orientation is transported with the device surface facing upward.

FIG. 10C is a view corresponding to FIG. 7C described above, and illustrates a state in which only the substrate W at the uppermost position is exposed above the liquid surface of the immersion tank 73 while the pair of inversion chucks 71 is in the half-open state. Thereafter, the inversion chuck support mechanism 72 lifts the pair of inversion chucks 71 by a height corresponding to the full pitch every time the relay transport mechanism OTR transports the substrate W. When this operation is repeated, all of the 25 substrates W are transported to the unloading position OP by the relay transport mechanism OTR.

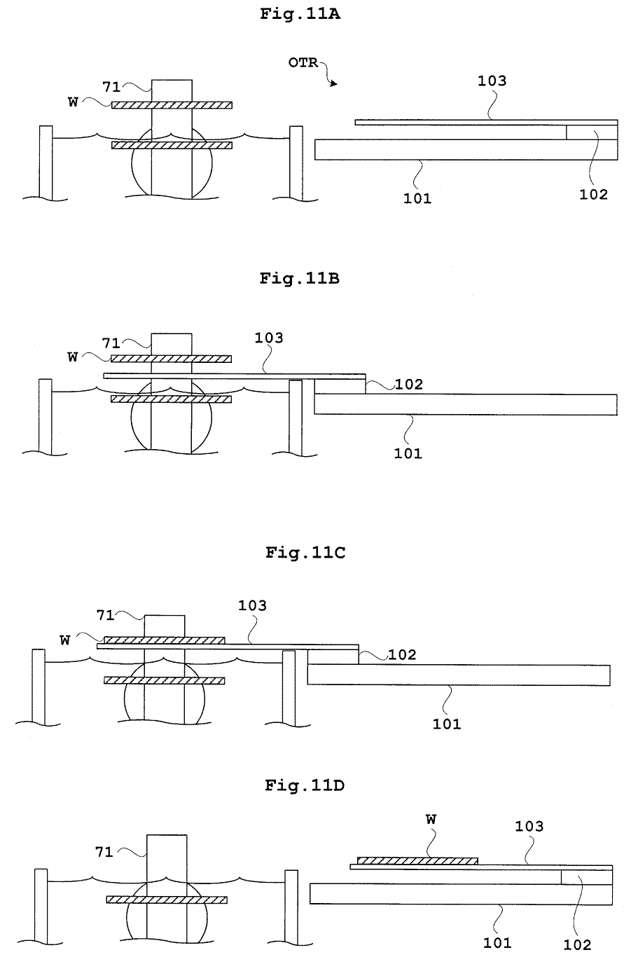

Hereinafter, how the relay transport mechanism OTR transports the substrate W in the horizontal orientation from the inversion chucks 71 in the state in each of FIGS. 7C and 10C will be described. FIG. 11A illustrates how the relay transport mechanism OTR is moved closer to the immersion tank 73 to transport the substrate W. As illustrated in FIG. 11A, the hand 103 of the relay transport mechanism OTR includes a slide mechanism 102 that advances and retracts the hand 103, and a support mechanism 101 that supports the slide mechanism 102. The slide mechanism 102 supports the base of the hand 103 and can advance the hand 103 as illustrated in FIG. 11B or can retract the hand 103 as illustrated in FIG. 11D. The support mechanism 101 can reciprocate the slide mechanism 102 and the hand 103 in the Y direction. The support mechanism 101 also rotates the hand 103 by 180°, whereby the hand 103 can face the immersion tank 73 or face the unloading position OP.

FIG. 11B illustrates how the hand 103 has been inserted between the substrate W above the liquid surface and the substrate W below the liquid surface by the slide mechanism 102. The hand 103 is ready to acquire the substrate W in the horizontal orientation by being in the state of FIG. 11B. The slide mechanism 102 at this time moves from the initial position to the forward position.

FIG. 11C illustrates how the pair of inversion chucks 71 has been lowered while maintaining the mutual positional relationship to bring the substrate W above the liquid surface into contact with the upper surface of the hand 103. When the substrate W is acquired by the hand 103 by lowering the inversion chucks 71 in this manner, the relay transport mechanism OTR can be configured without the configuration of moving the hand 103 up and down, so that a substrate processing system with a simple apparatus configuration and few failures can be provided.

FIG. 11D illustrates how the hand 103 that has acquired the substrate W is retracted to the support mechanism 101 of the relay transport mechanism OTR by the slide mechanism 102. Since the pair of inversion chucks 71 is in the half-open state, the pair of inversion chucks 71 supports the substrate W held in the liquid while allowing the substrate W to be pulled out by the hand 103. The slide mechanism 102 at this time moves from the forward position to the initial position.

The half-open state of the pair of inversion chucks 71 will be described. FIG. 12A is a cross-sectional view illustrating 25 substrates W immediately after being rotated by 90° or −90°, as shown in FIGS. 7B and 10B. The pair of inversion chucks 71 at this time is in the closed state, and both ends of the substrate W reach the deepest portions of the V-grooves 71a. When the pair of inversion chucks 71 presses both ends of the substrate W to fix the substrate W in this manner, the 25 substrates W do not slide off the pair of inversion chucks 71.

FIG. 12B is a cross-sectional view corresponding to FIG. 11B described above. The pair of inversion chucks 71 enters the closed state, and the hand 103 is inserted between the substrates W. In FIG. 12B and subsequent FIGS. 12C and 12D, the liquid surface in the immersion tank 73 is omitted.

FIG. 12C illustrates how the pair of inversion chucks 71 in the closed state is slightly separated from each other and is in the half-open state. When the pair of inversion chucks 71 is in the half-open state, both ends of the substrate W move from the deepest portions of the V-grooves and come into contact with the wall portions constituting the V-grooves. This state is a state in which the substrate W does not slide off the inversion chucks 71 unless the inversion chucks 71 are rotated, and is a state in which the substrate W itself is not fixed to the inversion chucks 71. Therefore, when the pair of inversion chucks 71 enters the half-open state, it is possible to pass one substrate W to the hand 103 above the liquid surface while holding the substrate W on standby in the liquid. However, in the state of FIG. 12C, the hand 103 is not yet in contact with the substrate W, thus necessitating that the substrate W be lowered with respect to the hand 103 to pass the substrate W to the hand 103.

FIG. 12D is a cross-sectional view corresponding to FIG. 11C described above. In FIG. 12D, the pair of inversion chucks 71 is slightly lowered from the state of FIG. 12C to bring the substrate W into contact with the hand 103. In the state of FIG. 12D, the substrate W is placed on the hand 103 and is at a position away from the wall surfaces of the V-grooves 71a of the inversion chucks 71. That is, in the state of FIG. 12D, the substrate W is not in contact with the inversion chucks 71. Therefore, when the slide mechanism 102 is operated to move the hand 103 in this state, the substrate W is pulled out without coming into contact with the inversion chucks 71.

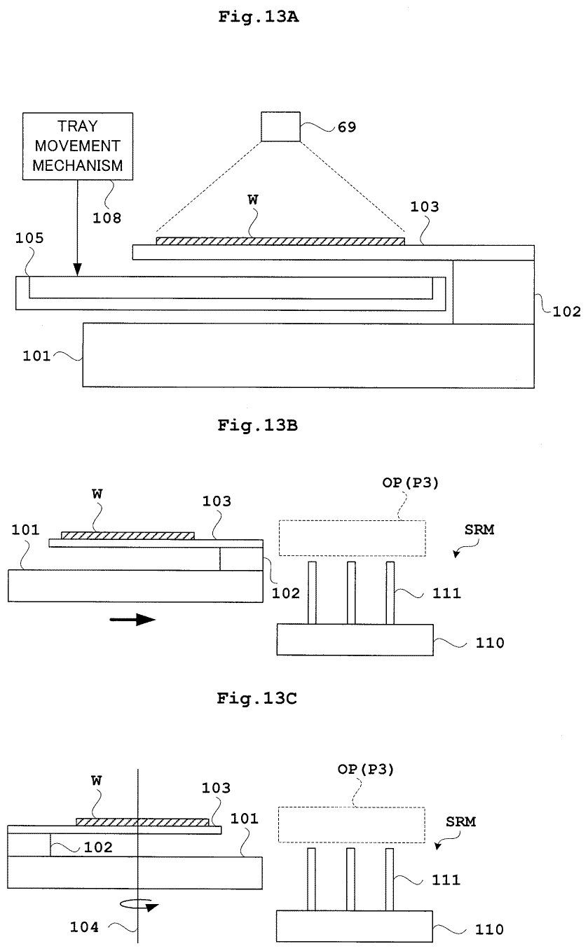

FIG. 13A illustrates the state of the substrate W in the horizontal orientation acquired from the pair of inversion chucks 71. The substrate processing system of the present embodiment has a configuration related to the water retention of the substrate W in the middle of the substrate transport path in the relay apparatus 6. A shower head 69 supplies a mist of pure water to the substrate W. Since being drawn in FIG. 1, the shower head 69 can be understood with reference to this figure. A tray 105 is a rectangular dish-shaped member inserted into a gap between the hand 103 and the support mechanism 101, and holds pure water supplied from the shower head 69 and dropped from the substrate W. Since the tray 105 hinders the operation of the slide mechanism 102, the tray 105 retracts in the X direction with respect to the slide mechanism 102 when the slide mechanism 102 operates as illustrated in FIGS. 11B and 11C. A tray movement mechanism 108 is configured to implement the operation of the tray 105.

FIG. 13B illustrates how the relay transport mechanism OTR transports the substrate W in the Y direction and moves closer to the unloading position OP. At this time, the hand 103 faces the immersion tank 73 side and the inversion chucks 71 side while gripping the substrate W.

FIG. 13C illustrates how the support mechanism 101 of the relay transport mechanism OTR then rotates by 180° around a rotation axis 104 extending in the Z direction. Such an operation of the support mechanism 101 causes the hand 103, which has faced the immersion tank 73 side, to face the unloading position OP side.

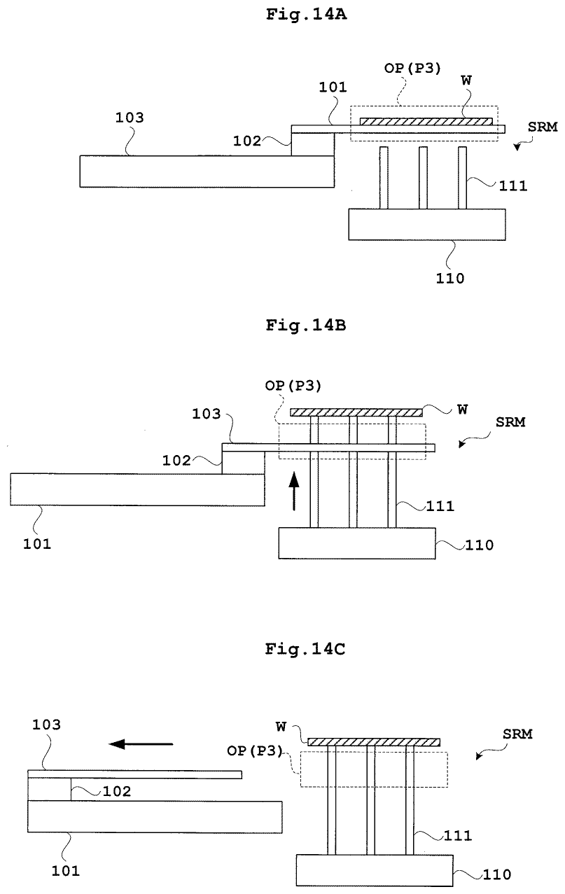

FIG. 14A illustrates how the slide mechanism 102 then performs a sliding operation to move the hand 103 holding the substrate W to the unloading position OP. At this time, the substrate W is located at the unloading position OP determined in the substrate processing system. The slide mechanism 102 at this time moves from the initial position to the forward position.

The rotation adjustment mechanism SRM is a mechanism provided immediately below the unloading position OP. The rotation adjustment mechanism SRM includes a plurality of (e.g., three) support pins 111 that expand in the Z direction. The support pins 111 are retractable in the Z direction. The support pins 111 expand and contract synchronously so that their tips are at the same height. A bottom plate 110 is configured to support the base ends of the support pins 111. In FIG. 14A, the tips of the support pins 111 are located below the unloading position OP.

FIG. 14B illustrates how the support pins 111 are then expanded, and the substrate W supported by the hand 103 is moved to the position above the unloading position OP. In this manner, the substrate W is passed from the hand 103 to the support pins 111.

FIG. 14C illustrates how the slide mechanism 102 then returns from the forward position to the initial position, and the hand 103 is retracted from the unloading position OP. The substrate W is supported above the unloading position OP by the support pins 111.

In this manner, each of the substrates W constituting the lot, which has been loaded to the loading position IP in the relay apparatus 6, is brought into the horizontal orientation, transported one by one, and reaches the unloading position OP. The substrate W transported to the unloading position OP is moved to the position above the unloading position OP by the support pins 111 of the rotation adjustment mechanism SRM, and then the position is adjusted by the rotation adjustment mechanism SRM.

### <6.6. Relay Apparatus: Notch Orientation>

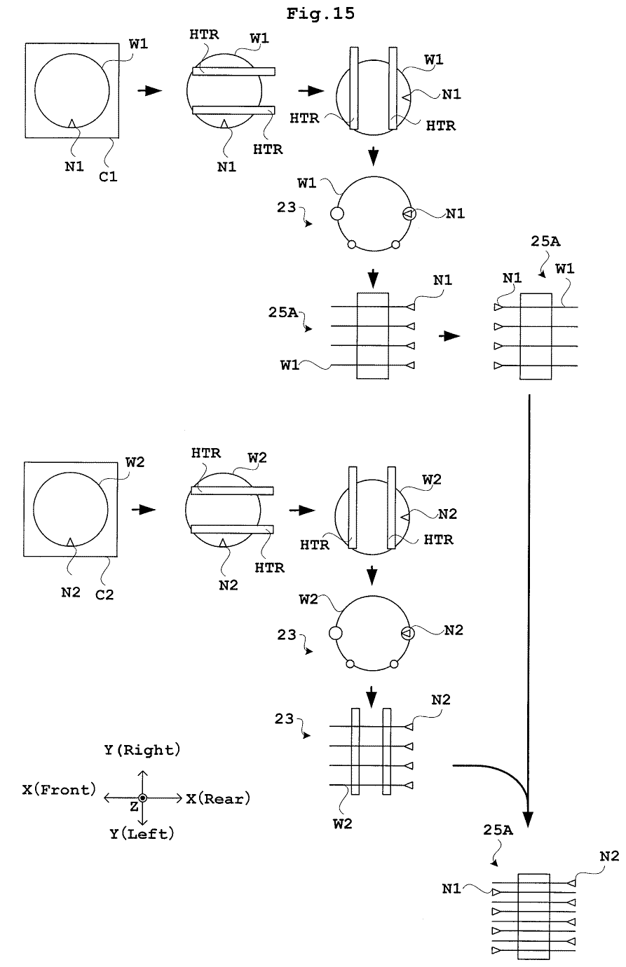

The transition of the orientation of the notch provided in the substrate W in the substrate transport so far will be described. Note that the notches of the substrate W housed in the carrier C described in FIG. 1 will be described below assuming that all the notches face the left direction as an example. FIG. 15 schematically illustrates the transition of the orientation of the notch. The batch processing apparatus 1 according to the embodiment is configured to combine each of the substrate groups housed in the two carriers C to form a lot, perform the batch process, release batch assembly in the lot, bring the substrates W into the horizontal orientation, and transport the substrates W one by one to the single-wafer processing apparatus 2. In FIG. 15, 25 first substrates W1 are housed in the first carrier C1 at full pitch, and 25 second substrates W2 are housed in a second carrier C2 at full pitch. The first substrates W1 and the second substrates W2 are substrate groups to be batch-assembled when constituting a lot.

Notches N1 of the first substrates W1 housed in the first carrier C1 all face left. The orientation of the notch N1 remains unchanged even if the first substrate W1 is gripped by the first substrate transport mechanism HTR. The first substrate transport mechanism HTR rotates the first substrate W1 counterclockwise by 90° because it is necessary to pass the first substrate W1 to the HVC orientation converter 23. Then, the notch N1, which has faced the left direction, faces the rear side of the substrate processing system.

Thereafter, the first substrate transport mechanism HTR collectively passes the first substrates W1 to the HVC orientation converter 23. The HVC orientation converter 23 rotates the passed substrate by 90°, but there is no change in the orientation of the notch N1 because the notch N1 at this time is located at the central axis of the rotation of the first substrate W1. Therefore, the orientation of the notch N1 remains unchanged depending on the operation of the HVC orientation converter 23.

The first substrate W1 brought into the vertical orientation by the HVC orientation converter 23 is passed to the pusher 25A. Thereafter, the pusher 25A rotates the first substrate W1 by 180° around the Z axis as described in FIG. 3D. At this time, the orientation of the notch N1 changes because the notch N1 is not located on the central axis of rotation. Specifically, the notch N1, which has faced the rear side, faces the front side.

On the other hand, notches N2 of the second substrate W2 housed in the second carrier C2 all face left similarly to the notches N1. The orientation of the notch N2 is changed backward by the first substrate transport mechanism HTR and passed to the HVC orientation converter 23.

As described in FIG. 3E, the second substrate W2 brought into the vertical orientation by the HVC orientation converter 23 is placed on the pusher 25A rotated by 180°. There is no change in the orientation of the notch N2 at this time.

In this way, the notches N1 of the first substrates W1 constituting the formed lot faces the front side, and the notches N2 of the second substrates W2 constituting the lot faces the rear side. Since the first substrates W1 and the second substrates W2 are alternately arrayed in the lot, the substrates with their notches facing the rear side and the substrates with their notches facing the front side are alternately arrayed as the substrates W constituting the lot. The substrates W constituting the lot are arrayed in a face-to-face manner.

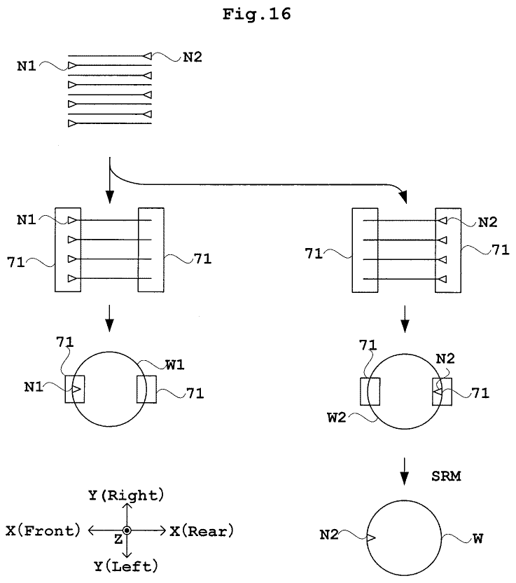

FIG. 16 illustrates how a lot that has completed various types of batch processes in the batch processing block 7 is converted into the horizontal orientation by the pair of inversion chucks 71. First, the lot is divided into an array of first substrates W1 and an array of second substrates W2. At this time, there is no change in the orientations of the notch N1 and the notch N2. Then, first, the orientation of the first substrate W1 is converted, and the first substrate W1 comes into the horizontal orientation. At this time, the first substrate W1 is rotated by 90°, but there is no change in the orientation of the notch N1 because the orientation of the notch N1 coincides with the rotation axis. Similarly, the orientation of the second substrate W2 is converted, and the second substrate W2 comes into the horizontal orientation. At this time, the second substrate W2 is rotated by −90°, but there is no change in the orientation of the notch N2 because the direction in which the notch N2 faces is parallel to the rotation axis. Ultimately, the inconsistency in the orientation seen between the notch N1 and the notch N2 is not resolved by the operation of the inversion chucks 71. When the first substrate W1 and the second substrate W2 are transported as they are to the single-wafer processing apparatus 2, the single-wafer process is completed while the orientations of the notches do not coincide, and the first substrate W1 is returned to the carrier C placed on the second load port 10. Similarly, the second substrate W2 is returned to another carrier C placed on the second load port 10. In each of the carriers C, the orientations of the notches in the substrates W to be stored coincide, but when the carriers C are compared with each other, the orientations of the notches are different by 180°.

To solve such inconsistency, in the substrate processing system of the embodiment, the rotation adjustment mechanism SRM is provided in the relay apparatus 6. The rotation adjustment mechanism SRM has a function of uniformly aligning the orientations of the notch N1 and the notch N2 by rotating the second substrate W2 by 180° without rotating the first substrate W1.

### <6.7. Relay Apparatus: Configuration of Rotation Adjustment Mechanism>

Next, the configuration of the rotation adjustment mechanism will be described. When the orientation of the notch on the first substrate W1 and the orientation of the notch on the second substrate W2 converted into the horizontal orientation by the underwater orientation converter 55 are different, the rotation adjustment mechanism SRM rotates the second substrate W2 at an angle different from the rotation angle of the first substrate W1 to cause the orientation of the notch on the first substrate W1 and the orientation of the notch on the second substrate W2 to coincide. FIG. 17 is a diagram of the single-wafer processing apparatus 2 as viewed from the batch processing apparatus 1 side. As illustrated in the figure, single-wafer processing chambers are laminated in the Z direction to form a laminate. For example, a single-wafer processing chamber 49c is disposed above a single-wafer processing chamber 48c, and a single-wafer processing chamber 47c is disposed below the single-wafer processing chamber 48c. Similarly, another single-wafer processing chamber is disposed above a single-wafer processing chamber 48a, and another single-wafer processing chamber is disposed below the single-wafer processing chamber 48a. Another single-wafer processing chamber is disposed above a single-wafer processing chamber 48b, and another single-wafer processing chamber is disposed below the single-wafer processing chamber 48a. Note that the single-wafer processing chamber is configured to process the substrates W in the horizontal orientation one by one, and details thereof will be described later.

FIG. 17 also illustrates that the relay apparatus 6 is disposed at a position sandwiched from above and below by single-wafer processing chambers. That is, a single-wafer processing chamber 49d is disposed above the relay apparatus 6, and a single-wafer processing chamber 47d is disposed below the relay apparatus 6.

As described above, the single-wafer processing chamber of the present embodiment includes a first laminate where three single-wafer processing chambers, to which the single-wafer processing chamber 48a belongs, are arrayed in the Z direction, a second laminate where three single-wafer processing chambers, to which the single-wafer processing chamber 48b belongs, are arrayed in the Z direction, and a third laminate where three single-wafer processing chambers, to which the single-wafer processing chamber 48c belongs, are arrayed in the Z direction. The single-wafer processing apparatus 2 of the present embodiment includes two single-wafer processing chambers provided at positions sandwiching the relay apparatus 6 from the Z direction. Therefore, the single-wafer processing apparatus 2 includes nine single-wafer processing chambers constituting a laminate and two single-wafer processing chambers provided above and below the relay apparatus 6, and includes a total of 11 single-wafer processing chambers.

As illustrated in FIG. 17, a shielding plate 16 is a part of the second wall surface 2B of the single-wafer processing apparatus 2, and is at a position surrounded by the relay apparatus 6, the single-wafer processing chambers 47d, 49d located above and below the relay apparatus 6, and the indexer block 4. The shielding plate 16 is provided to close a rectangular opening that cannot be closed by the relay apparatus 6 shorter than the single-wafer processing chamber 47d and the single-wafer processing chamber 49d in the X direction. When the shielding plate 16 is provided on the indexer block 4 side, the relay apparatus 6 can be located on a center robot CR1 side, so that the substrate W received from the rotation adjustment mechanism SRM at the unloading position OP can be passed to the single-wafer processing chamber without moving the center robot CR1 in the X direction.

Note that the hand holding the substrate W in the horizontal orientation included in the center robot CR1 is movable in the Z direction while the orientation of the substrate W is maintained. By configuring the center robot CR1 in this manner, the substrate W received from the rotation adjustment mechanism SRM can be passed to the single-wafer processing chambers located above and below the relay apparatus 6. By providing the relay apparatus 6 in the middle layer of the laminate of the single-wafer processing chambers, the rotation adjustment mechanism SRM is located at the intermediate position of the single-wafer processing block 8 in the Z direction. With this configuration, the rotation adjustment mechanism SRM is located near both the upper and lower single-wafer processing chambers. Therefore, it is not necessary to move the center robot CR1 by a long distance in the Z direction at the time of substrate transport, and the substrate W can be promptly transported from the rotation adjustment mechanism SRM to the single-wafer processing chamber.

The rotation adjustment mechanism SRM includes a plurality of support pins 111 capable of lifting and lowering the substrate W between a first position P1 on the upper side and a second position P2 on the lower side. The plurality of support pins 111 protrude and retract synchronously and move the substrate W between the first position P1, the second position P2, and an intermediate position P3, which is a position therebetween. The plurality of support pins 111 receive the substrate W from the relay transport mechanism OTR by lifting the substrate W held by the relay transport mechanism OTR to the first position P1, and place the received substrate W on a turntable 113 by lowering the received substrate W to the second position P2. The first position P1, the second position P2, and the intermediate position P3 correspond to the unloading position of the present invention. This configuration will be described in detail below.

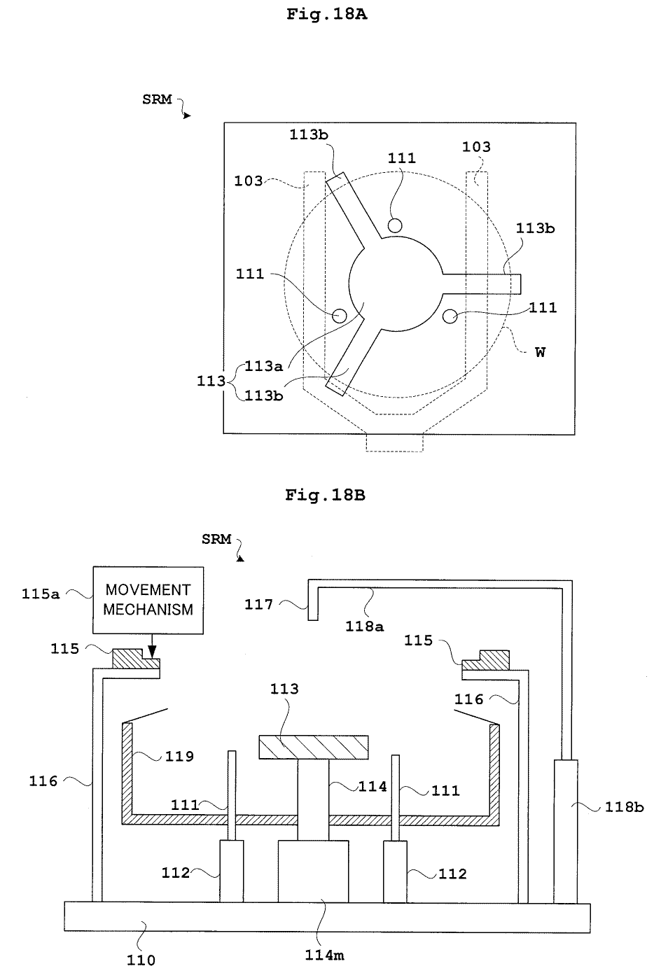

As illustrated in FIG. 18A, the rotation adjustment mechanism SRM includes the turntable 113 on which the substrate W in the horizontal orientation can be placed. The turntable 113 includes a disk-shaped central portion 113a and three extensions 113b radially extending from the central portion 113a. The turntable 113 is rotatable around the central portion 113a, and the turntable 113 rotates around the Z axis. The three extensions 113b rotate with the rotation of the central portion 113a.

The central portion 113a of the turntable 113 is provided to avoid the support pins 111, and this point will thus be described. The support pins 111 are provided at positions away from the peripheral edge of the central portion 113a of the turntable 113. The three support pins 111 are provided at positions corresponding to vertexes of an equilateral triangle having the same center of gravity as the rotation center of the turntable 113, and the central portion 113a of the turntable 113 does not interfere with the support pins 111 even if rotating.

The extensions 113b of the turntable 113 are configured to reliably place the substrate W in the horizontal orientation. The support pins 111 are provided at positions avoiding the plurality of extensions extending from the rotation center of the turntable 113 located at the initial position. The tips of the extensions 113b are configured to protrude from the substrate W when the substrate W in the horizontal orientation is placed on the turntable 113, and are configured to be able to reliably support three positions of the peripheral edge of the substrate W. The extensions 113b are sufficiently elongated to prevent interference with the support pins 111 as much as possible. When the turntable 113 is rotated, a state in which the positions of the extensions 113b and the positions of the support pins 111 coincide occurs. Since the support pins 111 contract in the initial state, the extensions 113b do not immediately collide with the support pins 111 even if the turntable 113 is rotated. However, when the support pins 111 expands while the extensions 113b are stopped at positions overlapping the support pins 111, the support pins 111 collide with the extensions 113b. Thus, there is a range of angles at which the turntable 113 cannot be stopped. Since the extensions 113b in the present embodiment are sufficiently elongated, this range of angles is as small as possible.

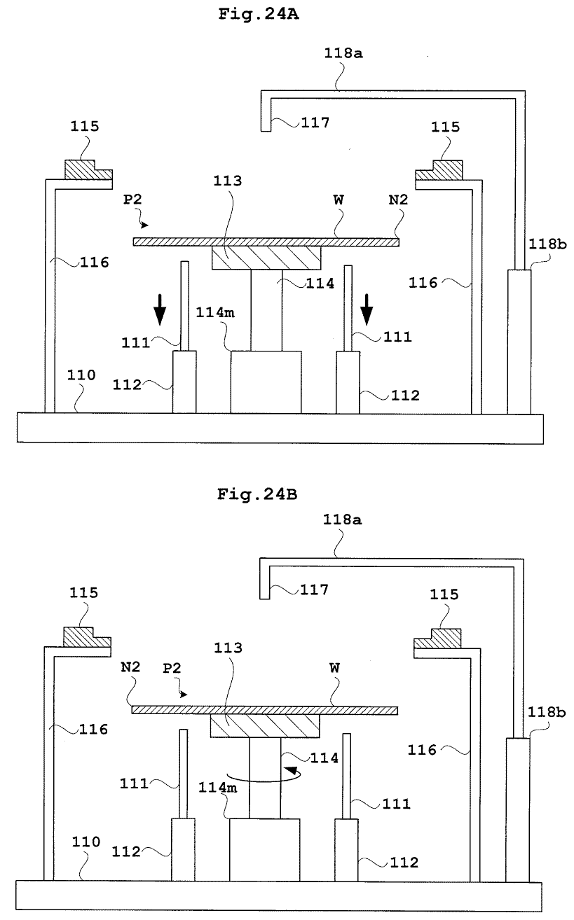

Note that the support pins 111 are provided at positions not interfering with the relay transport mechanism OTR that enters the position above the rotation adjustment mechanism SRM. That is, the three support pins 111 in the initial state are located in the space sandwiched between the pair of hands 103 located at the unloading position OP. In this way, when the support pin 111 receives the substrate W at the unloading position OP, the support pin 111 and the hand 103 do not collide with each other. The support pins 111 in the initial state are located below the second position P2 set below the unloading position OP. The second position P2 is detailed in FIG. 24A.

The rotation adjustment mechanism SRM includes the turntable 113 that can rotate the substrates in the horizontal orientation one by one at the unloading position OP to adjust the position of the notch on each substrate W. FIG. 18B illustrates a more detailed configuration of the rotation adjustment mechanism SRM. As illustrated in FIG. 18B, the rotation adjustment mechanism SRM includes the turntable 113 on which the substrate W is placed, a rotation shaft 114 that rotatably supports the turntable 113 and expands in the Z direction, and a rotation shaft drive motor 114m that drives the rotation shaft 114. In FIG. 18B, the extensions 113b included in the turntable 113 are omitted. The rotation shaft drive motor 114m is attached to the bottom plate 110 of the rotation adjustment mechanism SRM.

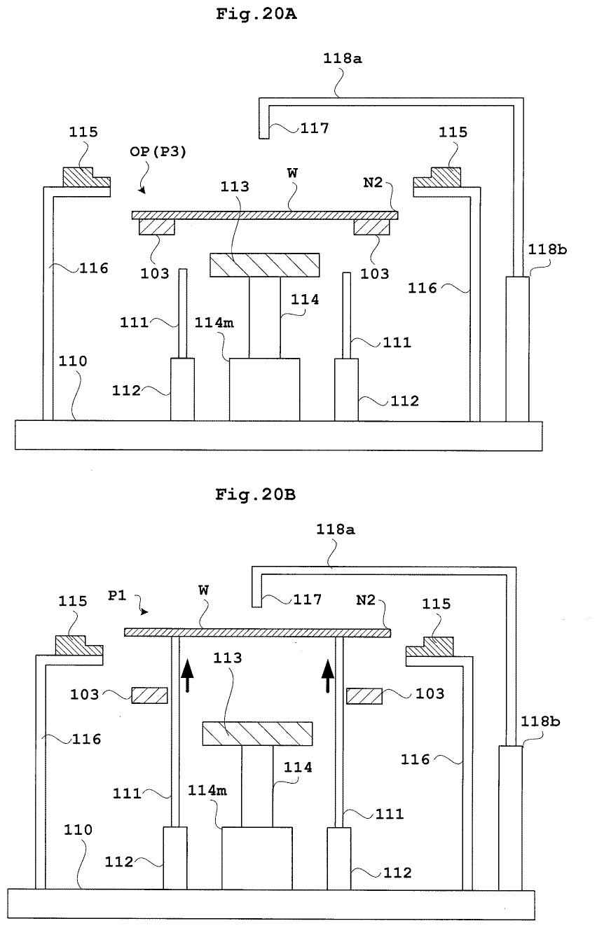

A support pin expansion/contraction mechanism 112 that expands/contracts the support pin 111 is provided at the base of each of the support pins 111. The support pin expansion/contraction mechanism 112 is attached to the bottom plate 110. The three support pin expansion/contraction mechanisms 112 operate synchronously to operate the respective support pins 111 while maintaining the state in which the tips of the support pins 111 are at the same height. Therefore, the three support pins 111 can expand and contract while supporting the substrate W in the horizontal orientation. In FIG. 18B, each of the support pins 111 is in a contracted state, and the tip of each of the support pins 111 is located below the turntable 113. When the support pin expansion/contraction mechanisms 112 synchronously expand the support pins 111, each of the support pins 111 comes into an expanded state as illustrated in FIG. 20B, and the tip of each of the support pins 111 is located above the turntable 113. In FIG. 18B, the depiction of one of the three support pins 111 is omitted. The support pins 111 and the support pin expansion/contraction mechanisms 112 correspond to a substrate lifting mechanism of the present invention.

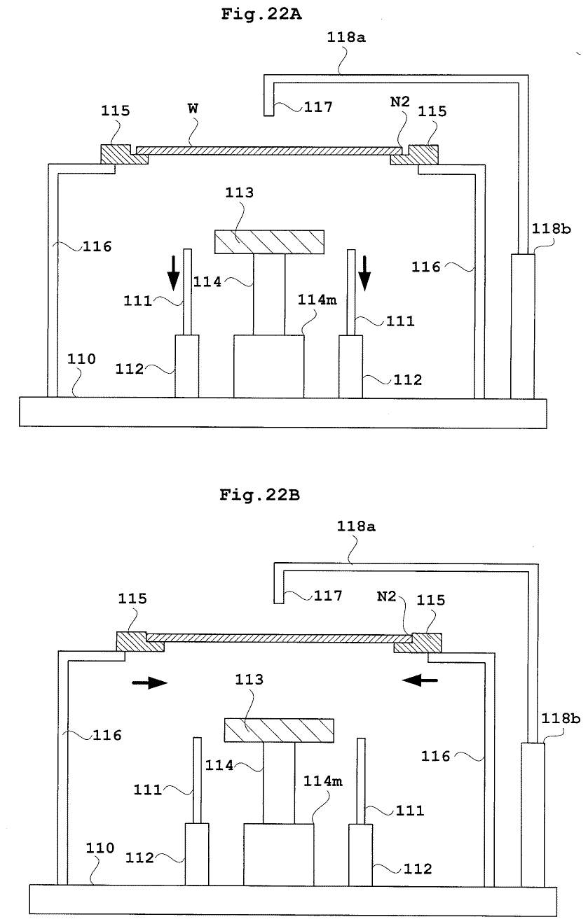

The rotation adjustment mechanism SRM includes a substrate shift mechanism that shifts the substrate W so that the center of the substrate W at the first position P1 coincides with the rotation center of the turntable 113. The substrate shift mechanism includes positioning chucks 115 each having an L-shaped cross section, and a movement mechanism 115a that reciprocates the pair of positioning chucks 115 in the radial direction of the substrate W. The positioning chucks 115 are provided on both the right and left sides of substrate W, and the pair of positioning chucks 115 is configured to hold both ends of the substrate W. The pair of positioning chucks 115 in the initial state is in the open state, and the positioning chucks 115 are at positions separated from each other. By approaching each other, the pair of positioning chucks 115 enters the closed state as illustrated in FIG. 22B, and holds the substrate W from both sides. In addition, the pair of positioning chucks 115 can also take the half-open state illustrated in FIG. 22A, but details of this state will be described later. The positioning chuck support 116 is a member that supports the positioning chuck 115, and has a slide surface on which the positioning chuck 115 is slidable. The positioning chuck 115 is located below the tip of the support pin 111 in the expanded state. The positioning chuck support 116 is attached to the bottom plate 110.

A water supply nozzle 117 is provided for the purpose of supplying pure water to the device surface of the substrate W. The water supply nozzle 117 is located above the substrate central portion, and is configured to spray pure water to the substrate W. The water supply nozzle 117 is coupled to an L-shaped water supply pipe 118a. The water supply pipe 118a is expandable in the Z direction. The operation of water supply pipe 118a is implemented by a water supply pipe drive mechanism 118b. The water supply pipe drive mechanism 118b is attached to bottom plate 110. The water supply nozzle 117, the water supply pipe 118a, and the water supply pipe drive mechanism 118b constitute a pure water replenishing mechanism of the present invention. The pure water replenishing mechanism is configured to replenish pure water to the substrate W received by the rotation adjustment mechanism SRM. According to such a configuration, the substrate W is not dried during the operation in the rotation adjustment mechanism SRM.

A guard 119 is provided for the purpose of preventing pure water sprayed from the water supply nozzle 117 from reaching each drive mechanism. The guard 119 includes a circular bottom plate and a cylindrical body connected to the end of the bottom plate. The support pin 111 is inserted through a through hole provided in the bottom plate of the guard 119, and a waterproof member (not illustrated) is provided in the through hole so that pure water does not leak from a gap between the support pins 111 and the bottom plate of the guard 119.

### <6.8. Relay Apparatus: Operation of Rotation Adjustment Mechanism>

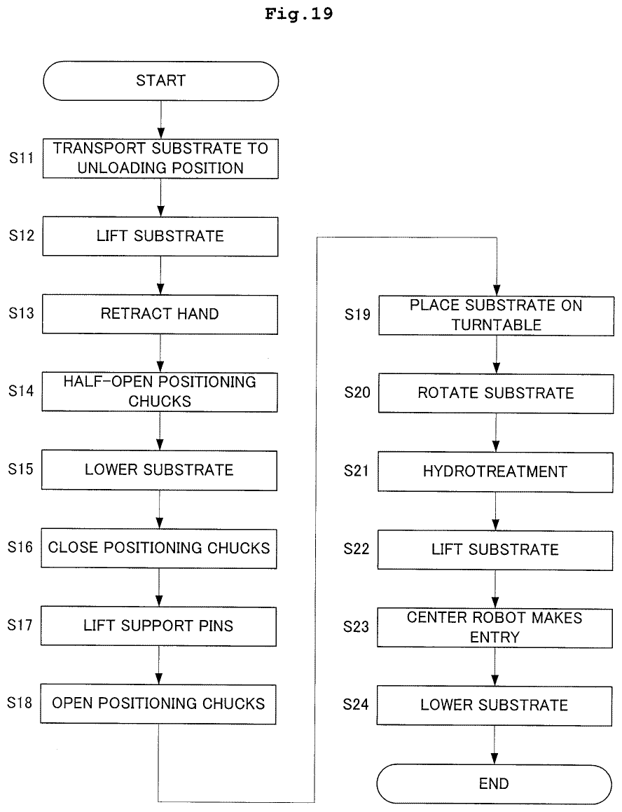

Hereinafter, the operation of the rotation adjustment mechanism SRM will be described. The rotation adjustment mechanism SRM performs an operation of receiving the substrate W in the horizontal orientation from the unloading position OP of the substrate W in the relay transport mechanism OTR, rotating the substrate W by a predetermined angle, and then passing the substrate W to the center robot CR1 of the single-wafer processing apparatus 2. FIG. 19 is a flowchart illustrating the operation of the rotation adjustment mechanism SRM in detail. Hereinafter, the operation of the rotation adjustment mechanism SRM will be described with reference to FIG. 19.

Step S11: First, the relay transport mechanism OTR transports the substrate W in the horizontal orientation to the unloading position OP (intermediate position P3). The rotation adjustment mechanism SRM at this time is in the initial state. In the rotation adjustment mechanism SRM in the initial state, the support pins 111 are in the contracted state, the pair of positioning chucks 115 is in the open state, and the water supply pipe 118a is in the expanded state. The unloading position OP is set above the turntable 113 and below the positioning chucks 115. Therefore, the substrate W at the unloading position OP is located above the tips of the support pins 111 in the contracted state and is located below the tips of the support pins 111 in the expanded state. However, in the rotation adjustment mechanism SRM in the initial state, since the support pins 111 and the water supply nozzle 117 are not located at the unloading position OP, the relay transport mechanism OTR can position the substrate W at the unloading position OP without colliding with these members. FIG. 20A illustrates the state of the rotation adjustment mechanism SRM in this step. As illustrated in FIG. 20A, the unloading position OP is sandwiched between the turntable 113 and the water supply nozzle 117. Reference numeral 103 in FIG. 20A indicates a hand included in the relay transport mechanism OTR. In FIG. 20A, the guard 119 described in FIG. 18B is omitted. Hereinafter, the operation of the rotation adjustment mechanism SRM will be described with the guard 119 being omitted appropriately.

FIGS. 20A to 28 describe how the notch N2, described in FIG. 16, is rotated by 180°. In FIG. 20A, it is assumed that the notch N2 is located on the right side of the substrate W. Hereinafter, the position of the notch N2 is appropriately indicated in the figure.

Step S12: FIG. 20B illustrates how the substrate W is moved to the first position P1 by the expansion of the support pins 111. When the support pins 111 expand, the tips of the support pins 111 come into contact with the substrate W, and then the substrate W is moved upward. In this manner, the substrate W is passed from the hand 103 of the relay transport mechanism OTR to the support pins 111 of the rotation adjustment mechanism SRM. Thereafter, the support pins 111 are expanded, and the substrate W is located above the pair of positioning chucks 115. At this time, the pair of positioning chucks 115 is in the open state, and the pair of positioning chucks 115 is separated enough to allow the passage of the substrate W.

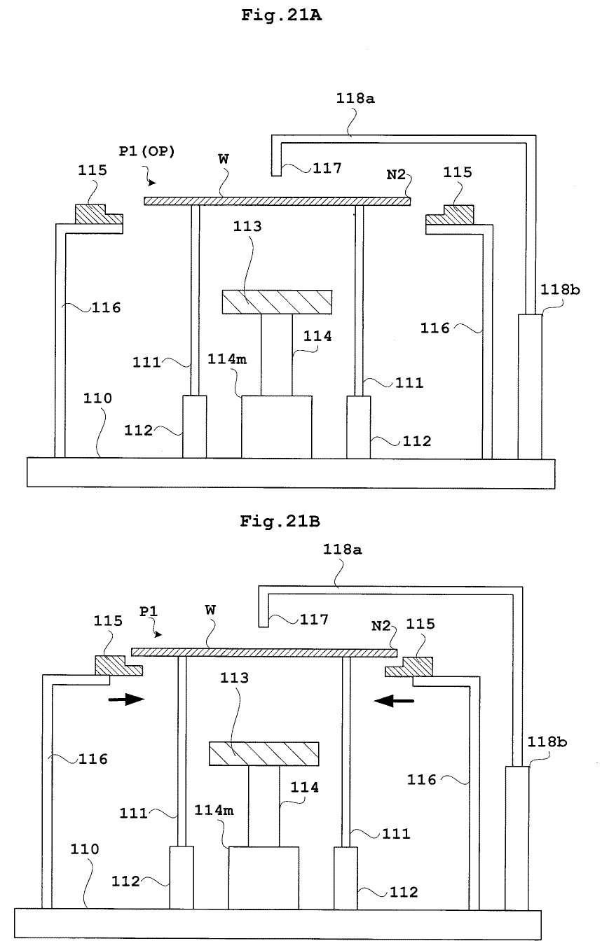

Step S13: FIG. 21A illustrates how the hand 103 of the relay transport mechanism OTR is then retracted from the unloading position OP. When the hand 103 is retracted in the Y direction, the substrate W can be placed on the turntable 113 by the expansion and contraction of the support pins 111. The rotation adjustment mechanism SRM of the embodiment can align the substrate W in the XY directions before placing the substrate W on the turntable 113. The following steps S14 to S18 are processes related to the alignment of the substrate W.

Step S14: FIG. 21B illustrates how the pair of positioning chucks 115 is in the half-open state and is ready to receive the substrate W. When the pair of positioning chucks 115 is in the half-open state, the substrate W cannot pass between the positioning chucks 115. Therefore, when the substrate W located above the positioning chucks 115 (first position P1) is moved downward, the substrate W comes into contact with the upper surfaces of the positioning chucks 115. Since the positioning chucks 115 are in the half-open state and are not in the closed state, the substrate W is not held between the positioning chucks 115 and is simply placed on the positioning chucks 115.

Step S15: FIG. 22A illustrates how the support pins 111 are then in the contracted state. When the support pins 111 are in the contracted state, the substrate W that has been supported by the support pins 111 is passed to the positioning chucks 115. Since a gap is provided between the side surface of the positioning chuck 115 and the peripheral edge of the substrate W, the substrate W at this time is not held between the positioning chucks 115.

Step S16: FIG. 22B illustrates how the positioning chucks 115 are then in the closed state. When the pair of positioning chucks 115 is in the closed state, both ends of the substrate W come into contact with the side surfaces of the positioning chucks 115, respectively. In this way, the substrate W is held between the pair of positioning chucks 115. At this time, the right end of the substrate W is pushed leftward by the right-side positioning chuck 115, and the left end of the substrate W is pushed rightward by the left-side positioning chuck 115. Even if the substrate W is close to the right-side positioning chuck 115 and the gap between the substrate W and the positioning chuck 115 is different between the left and right sides, the substrate W is pushed by the pair of positioning chucks 115 into a predetermined position. This situation would be the same even if the substrate W is closer to the left-side positioning chuck 115. That is, when the pair of positioning chucks 115 is changed from the half-open state to the closed state, the centering of the substrate W is executed. Since the contact portion of the positioning chuck 115 that comes into contact with the substrate W has an arc shape, the pair of positioning chucks 115 can center the substrate W not only in the X direction but also in the Y direction.

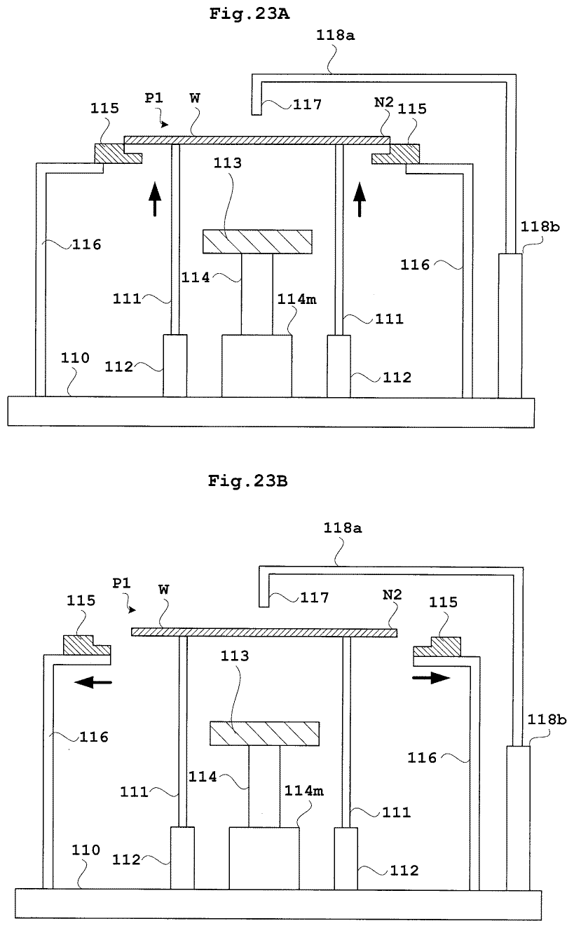

Step S17: FIG. 23A illustrates how the support pins 111 are then in the expanded state. When the support pins 111 are in the expanded state, the substrate W comes into contact with the tips of the support pins 111 and is pushed to the first position P1, thereby being extracted from the positioning chucks 115 this time. In this manner, the support pins 111 can acquire the centered substrate W from the pair of positioning chucks 115. Since the positioning chucks 115 in the closed state hold the substrate W with weak force, the substrate W is easily separated from the positioning chucks 115 when the support pins 111 push up the substrate W. Further, since the positioning chuck 115 has the L shape, the positioning chuck 115 does not have a member that prevents the lifting of the substrate W in contact with the side surface of the positioning chuck 115. Therefore, the substrate W is easily extracted from the positioning chucks 115 by the support pins 111.

Step S18: FIG. 23B illustrates how the pair of positioning chucks 115 then enter the open state. The positioning chucks 115 in the open state are separated enough to allow the passage of the substrate W. In this way, the substrate W is ready to be moved from the positioning chucks 115 to the turntable 113.

Step S19: FIG. 24A illustrates how the support pins 111 then return to the contracted state. When the support pins 111 are in the contracted state, the tips of the support pins 111 are located below the upper surface of the turntable 113. The substrate W at this time comes into contact with the turntable 113 as the support pins 111 contract, and the substrate W is no longer supported by the support pins 111. In this way, the substrate W is passed from the support pins 111 to the turntable 113. Since the turntable 113 is located at the second position P2, the substrate W passed to the turntable 113 is also present at the second position P2. The substrate W passed to the turntable 113 has already been processed for centering by the positioning chucks 115. Therefore, when the substrate W is placed on the turntable 113, the rotation center of the turntable 113 coincides with the center of the substrate W.

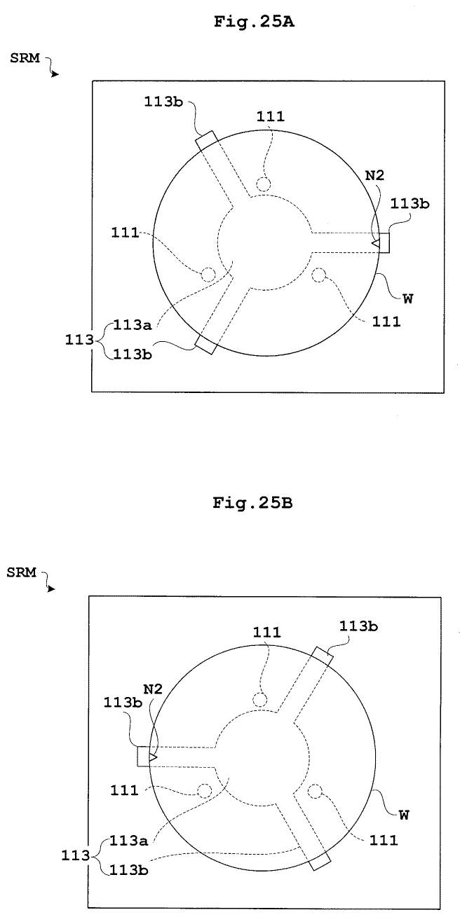

Step S20: FIG. 24B illustrates how the turntable 113 then rotates by 180° and the notch N2 located at the right end of the substrate W is moved to the left end of the substrate W. In this manner, the rotation adjustment mechanism SRM changes the position of the notch N2 on the second substrate W2. FIGS. 25A and 25B are plan views illustrating step S20. FIG. 25A illustrates the turntable 113 before rotation, and FIG. 25B illustrates the turntable 113 after rotation. As shown in FIG. 25A, the extensions 113b of the turntable 113 are at positions avoiding the support pins 111. These positions are the initial positions of the extensions 113b, and the initial positions are set so that the extensions 113b do not collide with the support pins 111 when the support pins 111 are in the expanded state as in steps S12, S13, S14, S17, and S18. The turntable 113 rotates by 180° around the Z axis from the state of FIG. 25A to the state of FIG. 25B. At this time, since the support pins 111 are in the contracted state, the tips of the support pins 111 do not collide with the extensions 113b of the turntable 113.

As illustrated in FIG. 25B, the extensions 113b of the turntable 113 after rotation are at positions avoiding the support pins 111. These positions are the positions of the extensions 113b after the rotation operation, and the positions after the rotation operation is set so that the extensions 113b do not collide with the support pins 111 when the support pins 111 are in the expanded state as in steps S22, S23 to be described later.

Note that the rotation operation of the second substrate W2 is performed while the state of FIG. 25A and the state of FIG. 25B are alternated, and hence this point will be described. The turntable 113 when the substrate W is received is at the initial position in FIG. 25A, but the turntable 113 after the rotation of the substrate W by 180° is at the position after the rotation operation. The rotated substrate W is eventually transported by the center robot CR1 of the single-wafer processing apparatus 2, and the turntable 113 is left behind from the substrate W. Since there are a plurality of second substrates W2 that need to be rotated, the subsequent second substrate W2 is placed on the turntable 113. The turntable 113 at this time is at the position after the rotation operation described in FIG. 25B. In this case, the turntable 113 rotates by 180° and returns to the initial position. Then, the second substrate W2 placed on the turntable 113 is rotated by 180° to adjust the position of the notch N2. As described above, the turntable 113 continuously performs the rotation process on the plurality of second substrates W2 while alternating between the initial position and the position after the rotation operation.

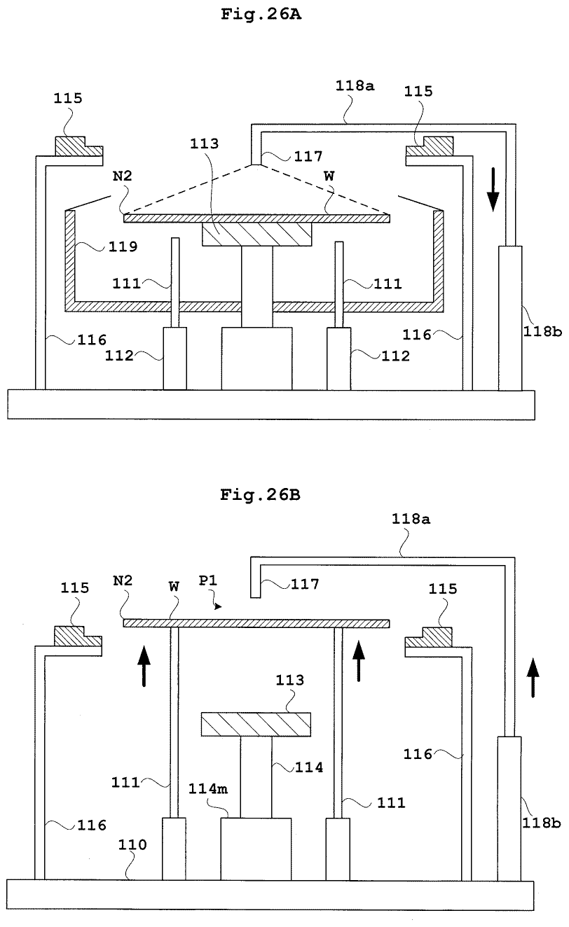

Step S21: FIG. 26A illustrates an operation when pure water is supplied to the substrate W after the rotation operation. To supply pure water to the substrate W, first, the water supply nozzle 117 is lowered to approach the substrate W. Then, pure water is shot radially from the water supply nozzle 117. The reach of the pure water is wide enough to supply the entire substrate W with pure water. The pure water supplied to the substrate W drips on the substrate W and is received by the guard 119 provided below the substrate W.

Step S22: FIG. 26B illustrates how the support pins 111 are then expanded and the substrate W is lifted to the first position P1. At this time, the water supply nozzle 117 returns to the initial position defined above the positioning chucks 115 so as not to collide with the substrate W being lifted. By separating the substrate W from the turntable 113 in this manner, the center robot CR1 of the single-wafer processing apparatus 2 is ready to acquire the substrate W.

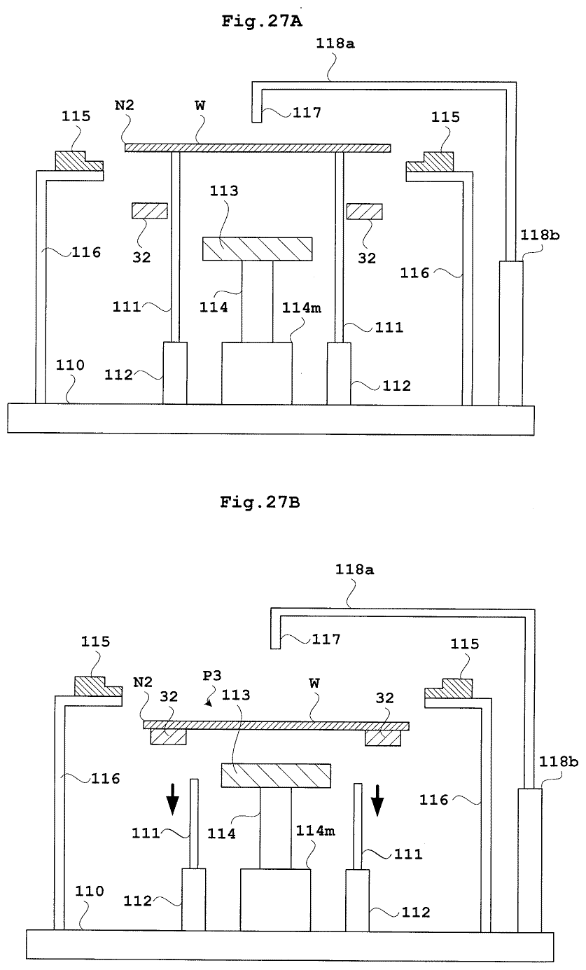

Step S23: FIG. 27A illustrates how the hand 32 of the center robot CR1 then enters the space (intermediate position P3) between the turntable 113 and the substrate W. Similarly to the hand 103 of the relay transport mechanism OTR, the hand 32 of the center robot CR1 is configured to hold the end of the substrate W so as not to collide with the support pins 111. In this way, the center robot CR1 is ready to acquire the substrate W.

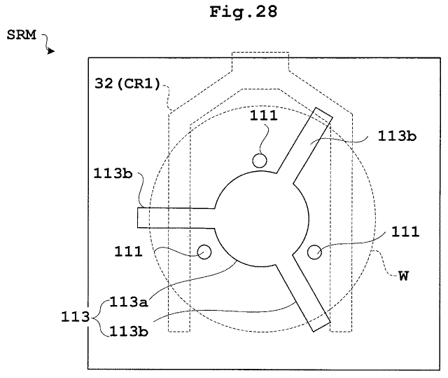

Step S24: FIG. 27B illustrates how the support pins 111 is then in the contracted state and the substrate W is lowered. When the support pins 111 are in the contracted state, the tips of the support pins 111 are located below the upper surface of the hand 32 of the center robot CR1, which is on standby at the intermediate position P3. The substrate W at this time comes into contact with the hand 32 as the support pins 111 contract, and the substrate W is no longer supported by the support pins 111. In this way, the substrate W is passed from the support pins 111 to the center robot CR1. The center robot CR1 takes the substrate W into the single-wafer processing apparatus 2, and the transport of the second substrate W2 is completed. FIG. 28 is a plan view illustrating a positional relationship between the hand 32 and the support pins 111 of the center robot CR1, and corresponds to FIG. 18A. As can be seen with reference to FIGS. 18A and 28, the rotation adjustment mechanism SRM is equipped with an entrance through which the hand 103 of the relay transport mechanism OTR enters, and an exit through which the hand 32 of the center robot CR1 enters.

Thereafter, by repeating steps S11 to S24, all the second substrates W2 held by the pair of inversion chucks 71 are transported to the single-wafer processing apparatus 2. Note that the rotation adjustment mechanism SRM at the time of transporting the first substrate W1 to the single-wafer processing apparatus 2 repeats the operations of steps S11 to S19 and steps S21 to S24, excluding step S20 described in FIG. 19. The difference between the transport method for the first substrate W1 and the transport method for the second substrate W2 is whether or not to perform the rotation operation of the substrate W described in FIGS. 24B, 25A, and 25B.

### 7. Single-Wafer Processing Apparatus: Indexer Block

The indexer block 4 is adjacent to the second load port 10. As illustrated in FIG. 1, the indexer block 4 includes the second load port 10 on which a carrier C, which houses a plurality of substrates W in the horizontal orientation at predetermined vertical intervals, is placed. Therefore, the second load port 10 is a placement table for the carrier C. On the second load port 10, a carrier C housing a plurality of substrates W that have completed the single-wafer substrate process is placed. Since the single-wafer processing apparatus 2 of the present embodiment is configured to receive the batch-processed substrate W from the relay apparatus 6 without passing through the second load port 10, an empty carrier C, which houses the batch-processed and single-wafer-processed substrates W, is placed on the second load port 10. Thus, the second load port 10 is used as the outlet of the substrate W in the single-wafer processing apparatus 2.

The internal structure of the indexer block 4 will be described. The indexer block 4 includes an indexer robot IR that transports the substrates W in the horizontal orientation one by one between the carrier C and a path 24, which is provided on the indexer block 4 side in the single-wafer processing block 8 to be described later.

The indexer robot IR houses the single-wafer-processed substrates W in the carrier C placed on the second load port 10. The indexer robot IR is equipped with a hand including a pair of gripping bodies that grips the substrate W in the horizontal orientation at their tips, and an arm supporting the hand. The arm includes a plurality of joints, with their tips connected to the hand and their base ends connected to the base of the arm provided in the indexer block 4. The indexer robot IR of the present embodiment is configured to receive the single-wafer-processed substrates W from the path 24a and house the substrate W in the second load port 10 outside the indexer block 4.

### 8. Single-Wafer Processing Apparatus: Single-Wafer Processing Block

The single-wafer processing block 8 is adjacent to the indexer block 4. That is, the single-wafer processing block 8 is provided on the back side of the indexer block 4 as viewed from the second load port 10. At the center portion of the single-wafer processing block 8 in the Y direction, a path 24a and the indexer robot IR are provided. The path 24a can be accessed by the indexer robot IR, and the center robot CR1 can place the single-wafer-processed substrates W on the path 24a. The center robot CR1 receives the batch-processed substrates W in the horizontal orientation one by one from the unloading position OP of the relay apparatus 6 and transports the substrates W to the single-wafer processing chamber. On the other hand, a path 24b is located behind the center robot CR1 and can be accessed by the center robot CR1 and a center robot CR2. The center robot CR2 is provided behind the path 24b. Each of the center robot CR1 and the center robot CR2 is a substrate transport robot that transport the substrates W in the horizontal orientation one by one, and can reciprocate in the Z direction. Therefore, the center robot CR1 and the center robot CR2 can access any of the single-wafer processing chamber, supercritical fluid chamber, and rotation adjustment mechanism SRM constituting the laminate.

The single-wafer processing block 8 includes a plurality of single-wafer processing chambers for performing the drying process on substrates in the horizontal orientation one by one. The single-wafer processing chamber of the embodiment includes a supercritical fluid chamber for drying the substrate W using supercritical fluid. Therefore, the substrate drying chamber mounted on the single-wafer processing apparatus 2 is a supercritical fluid chamber. The supercritical fluid chamber performs the drying process on the substrate W with, for example, carbon dioxide that has become the supercritical fluid. As the supercritical fluid, a fluid other than carbon dioxide may be used for drying. The supercritical state is obtained by setting carbon dioxide to the inherent critical pressure and critical temperature. Specifically, the pressure is 7.38 MPa and the temperature is 31° C. In the supercritical state, the surface tension of the fluid becomes zero, so that the gas-liquid interface does not affect the circuit pattern on the surface of the substrate W. Therefore, when the substrate W is subjected to the drying process using supercritical fluid, it is possible to prevent the occurrence of so-called pattern collapse in which the circuit pattern is collapsed on the substrate W.

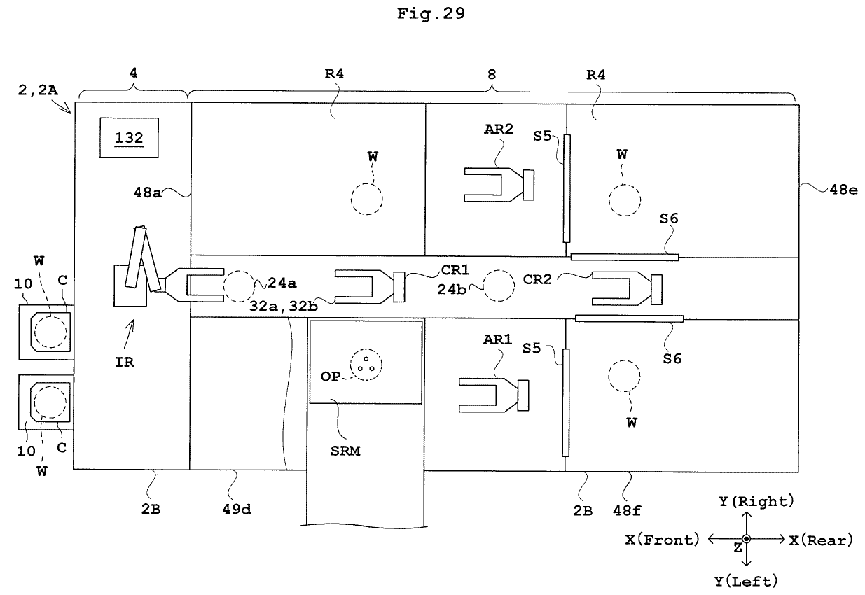

FIG. 29 illustrates the configuration of the single-wafer processing apparatus 2 according to the embodiment. The supercritical fluid chamber includes an inlet through which the substrate W before the drying process is loaded and an outlet through which the dry-processed substrate W is unloaded. The inlet is located in front of or behind the supercritical fluid chamber and includes an openable shutter S5. The outlet is located on the side wall of the supercritical fluid chamber and includes an openable shutter S6. The shutter S5 and the shutter S6 are closed during the drying process using supercritical fluid. The inlet of the supercritical fluid chamber faces a first wet transport robot AR1 and a second wet transport robot AR2, and the outlet faces the sheet transport region R3.

The first wet transport robot AR1 is provided in a region sandwiched between the rotation adjustment mechanism SRM and a supercritical fluid chamber 48f located on the left side of the sheet transport region R3. The second wet transport robot AR2, which is another robot, is provided in a region sandwiched between the single-wafer processing chamber 48a and a supercritical fluid chamber 48e located on the right side of the sheet transport region R3.

In addition, the single-wafer processing block 8 is equipped with a single-wafer processing chamber capable of performing chemical treatment. The single-wafer processing chamber is not a supercritical fluid chamber but a chemical treatment chamber including a chemical solution nozzle for supplying a chemical solution to the substrate W. Two chemical treatment chambers are provided in the single-wafer processing block 8, and one of those is the single-wafer processing chamber 48a. The other is the single-wafer processing chamber 49d located above the rotation adjustment mechanism SRM. As described in FIG. 17, the c single-wafer processing chamber 49d is located above the relay apparatus 6. The chemical solution may be isopropyl alcohol (IPA). The chemical treatment chamber is explosion-proof to the extent that flammable IPA can be handled. In this way, the chemical treatment chamber can safely perform the required IPA treatment before the drying process using supercritical fluid. However, the chemical solution used in the chemical treatment chamber of the present embodiment is not limited to IPA.

The position of the chemical treatment chamber can be relatively freely changed, but one of the two chemical treatment chambers is located on the right side of the sheet transport region R3, and the other is located on the left side. With such a configuration, it is not necessary to cause the center robot CR1 and the center robot CR2 located in the sheet transport region R3 to receive the IPA-treated substrate W. That is, the chemical-treated substrate W in the chemical treatment chamber is transported to the supercritical fluid chamber by the first wet transport robot AR1 or the second wet transport robot AR2, so that throughput is not reduced due to congestion of substrates W on standby for IPA treatment.

The first wet transport robot AR1 receives the substrates W before the drying process (chemical-treated substrates W) in the horizontal orientation one by one from the single-wafer processing chamber 49d, and loads the substrates W into one of the supercritical fluid chambers located on the left side of the sheet transport region R3 from the inlet described above. Therefore, the substrate transporting hand of the first wet transport robot AR1 can access all the inlets of the single-wafer processing chamber 49d and the nearby supercritical fluid chamber. Since the chambers are laminated in the Z direction, the hand can move in the height direction. Further, some chambers are located in front of the first wet transport robot AR1, while others are located behind the first wet transport robot AR1. Thus, the hand can face forward or backward.

The second wet transport robot AR2 has a configuration similar to that of the first wet transport robot AR1 described above. The second wet transport robot AR2 receives the substrates W before the drying process (chemical-treated substrates W) in the horizontal orientation one by one from the single-wafer processing chamber 48a, and loads the substrates W into one of the supercritical fluid chambers located on the left side of the sheet transport region R3 from the inlet described above. Therefore, the substrate transporting hand of the second wet transport robot AR2 can access all of the chambers forming the front laminate and the chambers forming the rear laminate.

The center robot CR1 and the center robot CR2 can access the outlet of the supercritical fluid chamber. The center robot CR1 includes a first hand 32a and a second hand 32b. The first hand 32a is located below the second hand 32b. Thus, the first hand 32a and the second hand 32b are laminated in the Z direction. The first hand 32a unloads the substrate W before the drying process from the rotation adjustment mechanism SRM, and transports the substrate W to the single-wafer processing chamber 49d. The second hand 32b unloads the dry-processed substrate W from either the supercritical fluid chamber located on the left side of the sheet transport region R3 or the supercritical fluid chamber located on the right side via the outlet described above.

The center robot CR2 includes a hand that transports the dry-processed substrate W. The center robot CR2 receives the dry-processed substrate W from the nearby supercritical fluid chamber, and transports the substrate W to the path 24b. The substrate W transported to the path 24b is transported to the path 24a by the second hand 32b of the center robot CR1. The indexer robot IR houses the substrate W on the path 24a in the carrier C.

### 9. Controller

The substrate processing system includes a first controller 131 related to the control of the batch processing apparatus 1, a second controller 132 related to the control of the single-wafer processing apparatus 2, and a third controller 136 related to the control of the relay apparatus 6. FIG. 1 can be referred to for each controller. Although not illustrated in FIG. 1, a storage corresponding to each controller is provided in the substrate processing system. Each of the controller 131, the controller 132, and the controller 136 include, for example, a central processing unit (CPU). A specific configuration of each controller is not limited, and for example, the controllers may be configured by a single processor, or each controller may be configured by an individual processor. The control related to the batch processing apparatus 1 may be configured by a plurality of processors, and this also applies to the single-wafer processing apparatus 2 and the relay apparatus 6.

Examples of the control related to the controller 131 include control related to the carrier transport mechanism 11, the first substrate transport mechanism HTR, the first orientation conversion mechanism 15, the second substrate transport mechanism WTR, the batch processing units BPU1 to BPU6, and the batch drying chamber DC. Examples of the control related to the controller 132 include control related to the center robot CR1, the center robot CR2, each chamber, the first wet transport robot AR1, the second wet transport robot AR2, and the indexer robot IR. Examples of the control related to the third controller 136 include control related to the full-pitch array substrate transport mechanism STR, the lot standby tank 65, the lifter LF65, the underwater orientation converter 55 (second orientation conversion mechanism), the rotation adjustment mechanism SRM, the relay transport mechanism OTR, and a pure water supply apparatus.

The storage stores programs, parameters, and the like related to control. The storage may be configured by a single device or may be configured by individual devices corresponding to the respective controllers. In addition, the substrate processing system of the present embodiment has no particular limitation on the configuration of the device that implements the storage.

### 10. Flow of Substrate Process

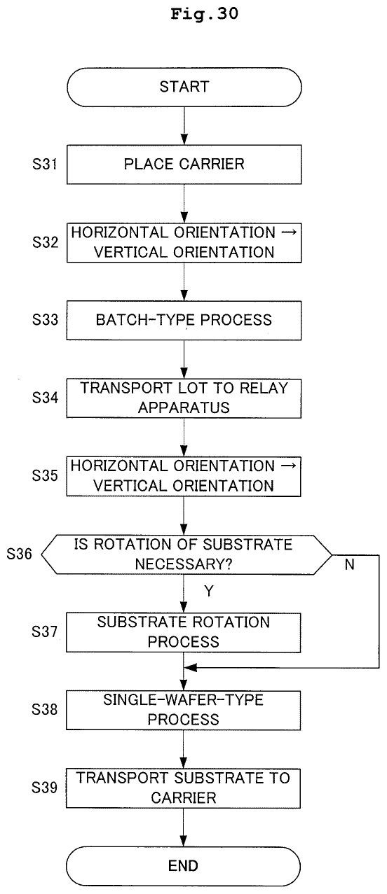

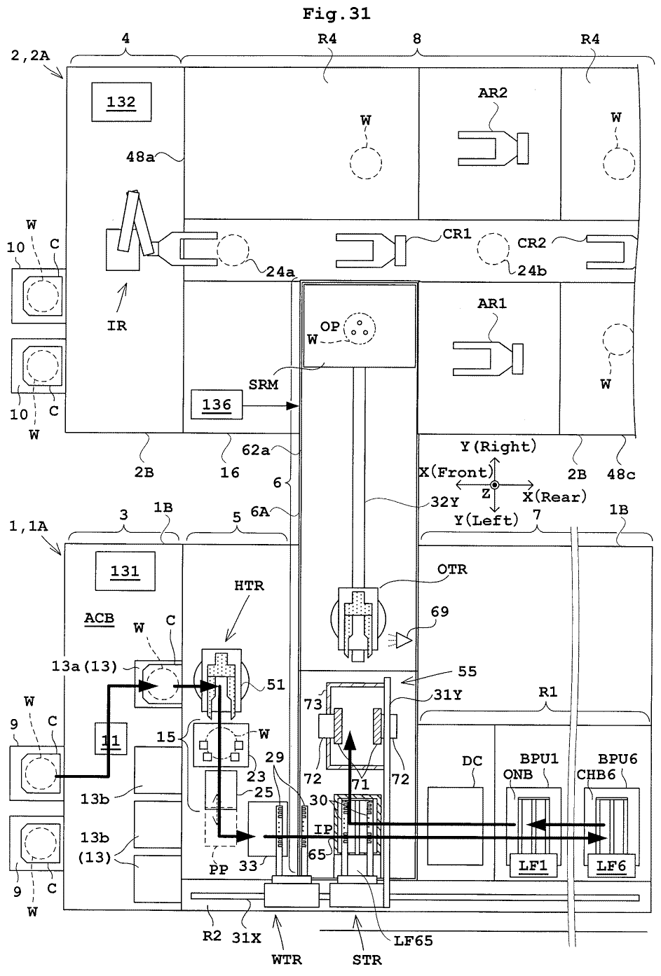

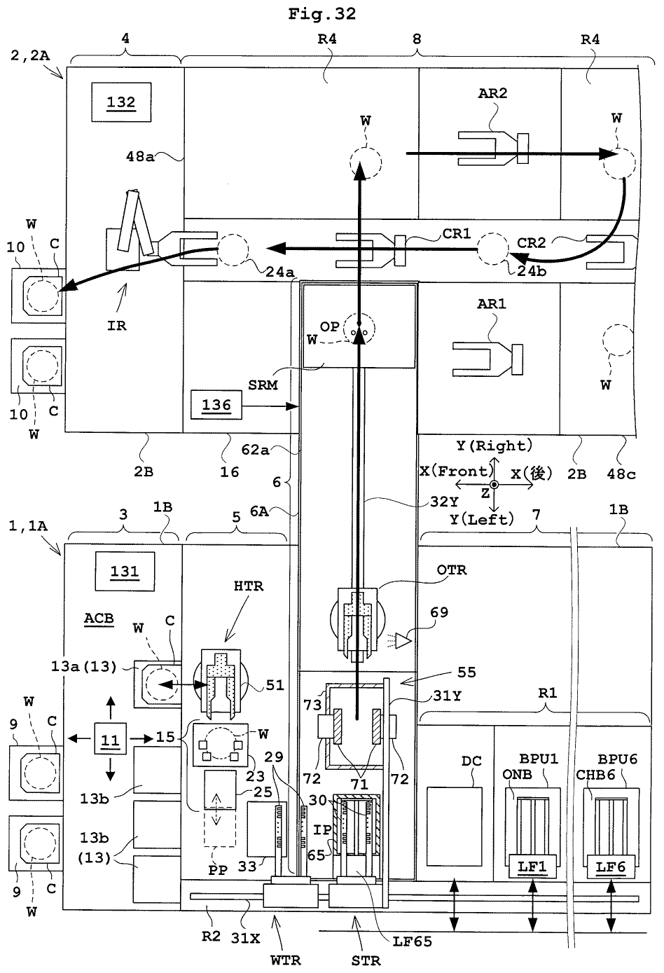

Hereinafter, the flow of the substrate process in the embodiment will be described with reference to the flowchart of FIG. 30. The substrate process according to the embodiment is performed by first performing the batch process on the substrate W and then performing the single-wafer process. The substrate W of the present embodiment is transported in the order of the first load port 9, the stocker block 3, the transfer block 5, the batch processing block 7, the relay apparatus 6, the single-wafer processing region R4, the indexer block 4, and the second load port 10, and the batch process and the single-wafer process are completed during that time (cf. FIGS. 31 and 32).

Step S31: The carrier C, which houses the array of the unprocessed substrates W in the horizontal orientation in the height direction, is placed on the first load port 9 in the batch processing apparatus 1. Thereafter, the carrier C is taken into the stocker block 3 and placed on the carrier placement shelf 13a. The carrier C may pass through the stock shelf 13b before being placed on the carrier placement shelf 13a. The carrier transport mechanism 11 moves the carrier C at this time. The first substrate transport mechanism HTR collectively extracts a plurality of substrates W in the horizontal orientation from the carrier C placed on the carrier placement shelf 13a and passes the substrates W to the HVC orientation converter 23.

Step S32: The HVC orientation converter 23 collectively converts the orientations of the plurality of received substrates W from the horizontal to vertical orientation and passes the orientations to the pusher mechanism 25. From the first substrate transport mechanism HTR, the HVC orientation converter 23 receives another set of substrates W derived from a carrier C that is different from the carrier C housing the plurality of substrates W subjected to orientation conversion, and converts the received substrates W from the horizontal to vertical orientation. The plurality of substrates W with the converted orientations are also passed to the pusher mechanism 25. In this manner, batch assembly is performed on the substrates W arrayed at full pitch, and the substrates W corresponding to two carriers are arrayed at half pitch in the pusher 25A. The lot generated in this way is transported to the substrate delivery position PP defined in the transfer block 5 by the pusher mechanism 25.

Step S33: The second substrate transport mechanism WTR receives the lot on standby at the substrate delivery position PP from the pusher mechanism 25 and passes the lot to the lifter LF6 that is on standby above the batch chemical treatment tank CHB6 in the sixth batch processing unit BPU6. At this time, the lot may pass through the dry lot support 33 before being placed on the lifter LF6. The lot is passed to the lifter LF6 to perform the phosphoric acid treatment on the lot. Therefore, the lot may be passed to one of the lifters LF2 to LF6 related to the phosphoric acid treatment. Hereinafter, the lot will be described as having been passed to the lifter LF6.

Thereafter, the lifter LF6 is lowered to the immersion position, and the batch-type phosphoric acid treatment is performed on the lot. The lot that has completed the phosphoric acid treatment is returned to the position above the batch chemical treatment tank CHB6 again by the lifter LF6 and passed to the second substrate transport mechanism WTR. The second substrate transport mechanism WTR passes the lot to the lifter LF1 that is on standby above the batch rinse processing tank ONB in the first batch processing unit BPU1. Thereafter, the lifter LF1 is lowered to the immersion position, and a batch rinse process is performed on the lot. In this way, a series of steps for the batch process is completed. The lot that has completed the batch process is returned to the position above the batch rinse processing tank ONB by the lifter LF1 and passed to the second substrate transport mechanism WTR.

Step S34: The second substrate transport mechanism WTR passes the batch-processed lot to the lifter LF65 that is on standby at the loading position IP. Thereafter, the lifter LF65 is lowered to the immersion position of the lot standby tank 65, and the lot is held on standby in pure water. When the plurality of substrates W are transported from the lot standby tank 65 to the immersion tank 73 of the underwater orientation converter 55, the lifter LF65 first moves the lot from the immersion position to the loading position IP. The full-pitch array substrate transport mechanism STR receives a row of the substrate in the vertical orientation from the lifter LF65 at the loading position IP, and transports the substrate row in the Y direction (rightward). As described above, since the full-pitch array substrate transport mechanism STR cannot transport the 50 substrates W constituting the lot at a time, it is necessary to perform the transport operation twice to transport all the substrates W constituting the lot to the underwater orientation converter 55. The second transport operation by the full-pitch array substrate transport mechanism STR is performed after all the substrates W transported in the first transport operation are unloaded from the immersion tank 73.

The pusher 55A located at the bottom of the immersion tank 73 of the underwater orientation converter 55 is lifted and receives the substrate row from the full-pitch array substrate transport mechanism STR that is on standby above the immersion tank 73. Thereafter, the pusher 55A is lowered to pass the substrate row to the inversion chucks 71.

FIG. 31 illustrates how the plurality of substrates W are collectively transported in the above steps S11 to S14.

Step S35: The inversion chucks 71 that have received the substrate row rotate left or right to collectively convert the orientations of the substrates W in the vertical orientation into the horizontal orientation.

Step S36: The third controller 136 determines whether it is necessary to rotate the substrate W transported to the unloading position OP of the rotation adjustment mechanism SRM by the relay transport mechanism OTR. When the substrate W at the unloading position OP is the first substrate W1 and it is not necessary to rotate the substrate W, the substrate W is not rotated and the process proceeds to step S38. When the substrate W at the unloading position OP is the second substrate W2, the process proceeds to step S37.

Step S37: The rotation adjustment mechanism SRM that has received the substrate W at the unloading position OP rotates the substrate W on the turntable 113 by 180°.

Step S38: The substrate W received in the single-wafer processing chamber 49d by the center robot CR1 is subjected to IPA treatment on the spot. The IPA-treated substrate is transported to the supercritical fluid chamber by the first wet transport robot AR1.

Step S39: The substrate W, which has completed the drying process by the supercritical fluid chamber, is received by the hand for transporting dry-processed substrates, which is included in each of the center robot CR1 and the center robot CR2. Then, the substrate W is transported from the supercritical fluid chamber to the path 24a or the path 24b. The indexer robot IR receives the processed substrate W from the path 24a and passes the substrate W to the carrier C placed on the second load port 10. In this way, the transport of the substrate W is completed. When the substrate W is transported to the path 24b, the center robot CR1 transports the substrate W to the path 24a. Thereafter, the substrate W is passed to the carrier C via the indexer robot IR.

FIG. 32 illustrates how the substrates W in the horizontal orientation are transported one by one in the above steps S35 to S39.

Since each step may be executed simultaneously, this point will be described. While the substrate W is subjected to the drying process in step S38, the substrate transport in the horizontal orientation with respect to the unloading position OP is continued. The substrate transport with respect to the unloading position OP is repeated until all the 11 single-wafer processing chambers included in the single-wafer processing apparatus 2 are in use. When one of the single-wafer processing chambers that has been in use becomes empty, the substrate transport to the unloading position OP is executed again. By performing the single-wafer substrate process in parallel in this manner, the throughput of the substrate processing system can be increased.

In step S35, after all of the plurality of substrates W in the horizontal orientation are transported from the relay apparatus 6 to the single-wafer processing apparatus 2, the underwater orientation converter 55 can receive a new substrate row. At this point, the full-pitch array substrate transport mechanism STR receives the substrate row on standby in the lot standby tank 65 from the lifter LF65 and passes the substrate row to the underwater orientation converter 55. As described above, according to the present embodiment, it is necessary to perform step S35 twice to transport one lot. Thus, step S35 may be executed simultaneously with step S38.

By appropriately repeating steps S35, S36, S37, S38, and S39, the substrate drying process by the single-wafer processing chamber can be completed while the batch assembly of the lot is released. When all the substrates W constituting the lot are returned to the carrier C placed on the second load port, the substrate process of the present embodiment is completed.

Note that the substrate process of the present embodiment is configured to process two carriers C at a time. That is, a first carrier C placed on the first load port 9 of the batch processing apparatus 1 and the substrate W housed in a second carrier C are respectively housed in a third carrier C and a fourth carrier C placed on the second load port 10 of the single-wafer processing apparatus 2.

In step S35, all the substrates W to be orientation-converted are derived from the first carrier C. Therefore, the relay apparatus 6 transports only the first substrate W1 housed in the first carrier C to the single-wafer processing apparatus 2. The indexer robot IR houses all the first substrates W1 related to the first carrier C transported in this manner in the third carrier C.

When all the substrates W according to the first carrier C are transported from the underwater orientation converter 55, step S35 is executed again. In this case, all the substrates W to be orientation-converted are derived from the second carrier C. Therefore, the relay apparatus 6 transports only the second substrate W2 housed in the second carrier C to the single-wafer processing apparatus 2. The indexer robot IR houses all the second substrates W2 related to the second carrier C transported in this manner in the fourth carrier C.

In this way, the substrate W housed in the first carrier C and the substrate W housed in the second carrier C fit into the third carrier C and the fourth carrier C, respectively, without being mixed.

The substrate W held by the rotation adjustment mechanism SRM is received by the center robot CR1 and finally passed to the carrier C by the indexer robot IR. During this time, the substrate is transported while its orientation changes in a certain mode. For example, when the notch on the substrate W held by the rotation adjustment mechanism SRM faces forward, the notch passes through each chamber and each path while facing forward or backward, and is finally returned to the carrier C with the notch facing backward. Depending on the type, the chamber may complete the process with a half turn of the unprocessed substrate or without turning the unprocessed substrate. However, since each of the substrates held by the rotation adjustment mechanism SRM is subjected to the same process and reaches the carrier C, all the substrate-processed substrates W housed in the carrier C are in a state where the directions in which the notches face are unified.

In the embodiment, since the substrates W with different notch orientations are transported to the unloading position OP by the relay transport mechanism OTR, the first substrate W1 and the second substrate W2 are housed in the carrier C in a state where the notch orientations are different unless the rotation adjustment of the substrates is performed. However, in the present embodiment, since the rotation adjustment mechanism SRM that selectively rotates only the second substrate W2 is provided, the second substrate W2 is subjected to the single-wafer process in a state where the orientation of the notch is the same as that of the first substrate W1. Therefore, there is no difference in the orientation of the notch between the substrate-processed first substrate W1 and the substrate-processed second substrate W2.

As described above, according to the configuration of the embodiment, it is possible to realize the requirements for the substrate processing system in the substrate processing system configured by coupling the batch processing apparatus 1 and the single-wafer processing apparatus 2 through the relay apparatus 6. The relay apparatus 6 of the present invention is equipped with the rotation adjustment mechanism SRM including the turntable 113 capable of adjusting the position of the notch on the substrate W at the loading position IP where the relay apparatus 6 acquires the substrate or at the unloading position OP where the relay apparatus 6 dispenses the substrate. The orientation of the substrate W dispensed from the relay apparatus 6 to the single-wafer processing apparatus 2 can be changed as desired by the rotation adjustment mechanism SRM. Changing the operation of the rotation adjustment mechanism SRM enables the orientation of the substrate W passed to the single-wafer processing apparatus 2 to be aligned in a predetermined direction.

According to the present invention, it is possible to provide a substrate processing system capable of aligning the orientations of the substrates W in a predetermined direction even if the substrates W are arrayed in a face-to-face manner to form a lot. When two substrate groups are combined and arrayed such that the device surface of the first substrate W1 and the device surface of the second substrate W2 face each other, a lot in which the first substrates W1 and the second substrates W2 are alternately arrayed is formed. Thereafter, when the lot is sorted into the first substrate W1 and the second substrate W2, the orientation of the notch on the first substrate W1 and the orientation of the notch on the second substrate W2 are different from each other. According to the above configuration, the rotation adjustment mechanism SRM rotates the substrate so that the rotation angle of the first substrate W1 and the rotation angle of the second substrate W2 are different from each other, whereby the orientation of the notch on the first substrate W1 and the orientation of the notch on the second substrate W2 can be caused to coincide.

According to the present embodiment, the substrate W is moved up and down between the first position P1 on the upper side, the intermediate position P3, and the second position P2 on the lower side, and can receive the substrate W, rotate the substrate W, and dispense the substrate W. According to such a configuration, the configuration of the rotation adjustment mechanism SRM can be made simpler.

According to the present embodiment, the substrate W at the first position P1 is shifted by the positioning chucks 115 so that its center coincides with the center position of the turntable 113. With this configuration, the orientation of the substrate W can be reliably set to a predetermined orientation, and the substrate W can be reliably transported by the center robot CR1 by placing the substrate W at an ideal position.

The plurality of support pins 111 protrude and retract synchronously, and are provided at positions avoiding the plurality of extensions 113b extending from the rotation center of the turntable 113 located at the initial position. With such a configuration, it is possible to reliably configure the rotation adjustment mechanism SRM including both the plurality of support pins 111 and the mechanism for rotating the substrate.

The present invention is not limited to the configuration of the embodiment described above, and can be modified as follows.

### <Modification 1>

The substrate processing system of the embodiment has been configured to include one relay apparatus 6, but the present invention is not limited to this configuration. One batch processing apparatus 1 may include a plurality of single-wafer processing apparatuses 2, and each single-wafer processing apparatus 2 may include the relay apparatus 6. The substrate processing system of the present modification has a configuration including a plurality of relay apparatuses 6.

### <Modification 2>

In the substrate processing system of the embodiment, the substrate W has been dried by the supercritical fluid chamber, but the present invention is not limited to this configuration. The substrate W may be dried by spin drying.

### <Modification 3>

The substrate processing system of the embodiment has been configured with the turntable 113 rotating the second substrate W2 by 180°, but the present invention is not limited to this configuration. The first substrate W1 may be rotated by 180° while the second substrate W2 may not be rotated.

### <Modification 4>

The substrate processing system of the embodiment has been configured not to rotate the first substrate W1, but the present invention is not limited to this configuration. For example, the first substrate W1 may be rotated by −n°, and the second substrate may be rotated by (180−n)°. With this configuration, even in a substrate processing system where the center robot CR1 receives the substrate from an oblique direction inclined by n° with respect to the rotation adjustment mechanism SRM, the substrate W can be housed in the carrier C in the same manner as in the embodiment.

### <Modification 5>

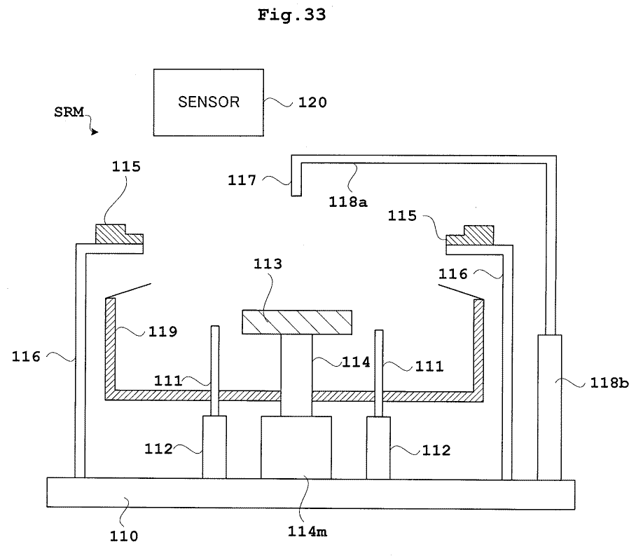

As illustrated in FIG. 33, the rotation adjustment mechanism SRM of the substrate processing system of the embodiment may include a sensor 120 that detects the position of the notch on the substrate W. As the sensor 120, for example, a reflective optical sensor or a transmissive optical sensor is used. According to such a configuration, since the sensor 120 detects the position of the notch on the substrate W on the turntable 113, it is possible to actually measure and correct a slight deviation in orientation seen between the substrates.

### <Modification 6>

The rotation adjustment mechanism SRM of the substrate processing system of the embodiment has been provided at the unloading position OP of the relay apparatus 6, but the present invention is not limited to this configuration. The rotation adjustment mechanism SRM may be provided on the loading position IP side. Specifically, the loading position IP side is a position sandwiched between the underwater orientation converter 55 and the relay transport mechanism OTR. According to the present modification, notch alignment is executed before the substrate W is gripped by the relay transport mechanism OTR. In this way, the configuration of the relay apparatus 6 at the unloading position OP can be simplified.

What is claimed is:

1. A substrate processing system that continuously performs a batch process to collectively perform a plurality of substrates, and a single-wafer process to process substrates one by one, the substrate processing system comprising:
a batch processing apparatus that performs the batch process;
at least one single-wafer processing apparatus that performs the single-wafer process on a substrate subjected to the batch process;
at least one relay apparatus with two positions defined, the two positions being a loading position to receive a substrate subjected to the batch process from the batch processing apparatus and an unloading position to pass the substrate received at the loading position to the single-wafer processing apparatus,
wherein
the batch processing apparatus includes at least one batch processing tank capable of collectively performing an immersion process on a plurality of substrates in a vertical orientation,
the single-wafer processing apparatus includes a plurality of single-wafer processing chambers capable of performing a drying process on substrates in a horizontal orientation one by one, and
the relay apparatus includes
an orientation conversion mechanism capable of converting a plurality of substrates from the vertical orientation to the horizontal orientation on a side of the loading position,
a relay transport mechanism provided between the loading position and the unloading position, and capable of transporting the substrates in the horizontal orientation one by one to the unloading position along a substrate transport path, and
a rotation adjustment mechanism including a turntable capable of adjusting a position of a notch on each of the substrates in the horizontal orientation by rotating the substrates one by one on the side of the loading position or at the unloading position.

2. The substrate processing system according to claim 1, wherein
the batch processing apparatus includes a substrate holding mechanism that supports a first substrate group in the vertical orientation and a second substrate group in the vertical orientation, the substrate holding mechanism supporting a lot formed by combining a first substrate constituting the first substrate group and a second substrate constituting the second substrate group to cause a device surface of the first substrate and a device surface of the second substrate to face each other,
the relay apparatus includes a substrate group sorting mechanism capable of sorting a lot into the first substrate and the second substrate,
the orientation conversion mechanism collectively converts the first substrate sorted and the second substrate sorted from the vertical orientation to the horizontal orientation, and
when an orientation of a notch on the first substrate and an orientation of a notch on the second substrate are different, the first substrate and the second substrate having been converted into the horizontal orientation by the orientation conversion mechanism, the rotation adjustment mechanism rotates the second substrate at an angle different from a rotation angle of the first substrate to cause the orientation of the notch on the first substrate and the orientation of the notch on the second substrate to coincide.

3. The substrate processing system according to claim 1, wherein
the rotation adjustment mechanism includes a substrate lifting mechanism capable of lifting a substrate between a first position on an upper side and a second position on a lower side, and
the substrate lifting mechanism lifts a substrate, held by the relay transport mechanism at an intermediate position between the first position and the second position, to the first position to receive the substrate from the relay transport mechanism, and lowers the substrate received to the second position to place the substrate on the turntable.

4. The substrate processing system according to claim 3, wherein the rotation adjustment mechanism includes a substrate shift mechanism that shifts the substrate at the first position to cause a center of the substrate to coincide with a rotation center of the turntable.

5. The substrate processing system according to claim 3, wherein the substrate lifting mechanism includes a plurality of pins that protrude and retract synchronously, and is provided at a position avoiding a plurality of extensions extending from a rotation center of the turntable located at an initial position.

6. The substrate processing system according to claim 1, wherein the rotation adjustment mechanism includes a pure water replenishing mechanism that replenishes pure water to a substrate received.

7. The substrate processing system according to claim 1, wherein the rotation adjustment mechanism includes a sensor that detects a position of a notch on a substrate on the turntable.
